(19) United States
(12) Patent Application Publication
(10) Pub. No.: US 2025/0285657 A1
(43) Pub. Date: Sep. 11, 2025

(54) MEMORY DEVICE

(71) Applicant: Kioxia Corporation, Tokyo (JP)

(72) Inventors: Hiroiki HAYAKAWA, Kyoto (JP); Ryota NARASAKI, Ibaraki (JP); Takamitsu OCHI, Nagoya (JP)

(73) Assignee: Kioxia Corporation, Tokyo (JP)

(21) Appl. No.: 18/830,337

(22) Filed: Sep. 10, 2024

(30) Foreign Application Priority Data
Mar. 11, 2024 (JP) 2024-037270

(51) Int. Cl. G11C 5/10; G11C 11/4091

(52) U.S. Cl. CPC G11C 5/10; G11C 11/4091

(57) ABSTRACT

A first insulator is on a surface of the first semiconductor on a side of a second direction crossing the first direction. A first conductor is on a surface of the first insulator on the side of the second direction. A second insulator is on a surface of the first semiconductor on a side of a third direction opposite to the second direction. A second semiconductor is located further in the third direction than the first semiconductor. A third insulator is on a surface of the second semiconductor on the side of the third direction. A second conductor is on a surface of the third insulator on the side of the third direction. A fourth insulator is on a surface of the second semiconductor on the side of the second direction. A third conductor is in contact with the second insulator and the fourth insulator.

### CROSS-REFERENCE TO RELATED APPLICATION

This application is based upon and claims the benefit of priority from prior Japanese Patent Application No. 2024-37270, filed Mar. 11, 2024, the entire contents of which are incorporated herein by reference.

### FIELD

Embodiments described herein relate generally to a memory device.

### BACKGROUND

A memory device including three-dimensionally arrayed memory cells is known. Examples of the memory device include a dynamic random access memory (DRAM). Memory cells of the DRAM store data by using charge accumulated in a capacitor.

### BRIEF DESCRIPTION OF THE DRAWINGS

FIG. 1 illustrates functional blocks of a memory device according to a first embodiment.

FIG. 2 illustrates components of a memory cell of the memory device according to the first embodiment and coupling of the components.

FIGS. 3, 4 and 5 are plan views of a part of a memory cell array of the memory device according to the first embodiment.

FIG. 6 illustrates an example of a cross-sectional structure of a part of the memory cell array of the memory device according to the first embodiment.

FIGS. 7 and 8 illustrate examples of a cross-sectional structure of a part of the memory device according to the first embodiment.

FIGS. 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, and 63 illustrate examples of cross-sectional structures during manufacturing steps of the memory device according to the first embodiment.

FIG. 64 illustrates an example of a cross-sectional structure of a part of a memory cell array of a memory device according to a second embodiment.

FIG. 65 illustrates a relationship between semiconductors and concentrations of a dopant in the memory device according to the second embodiment.

FIG. 66 illustrates an example of a cross-sectional structure during a manufacturing step of the memory device according to the second embodiment.

FIG. 67 illustrates a relationship between semiconductors and concentrations of a dopant in the memory device according to the second embodiment.

FIG. 68 illustrates an example of a cross-sectional structure during a manufacturing step of the memory device according to the second embodiment.

FIG. 69 illustrates a relationship between semiconductors and concentrations of a dopant in the memory device according to the second embodiment.

FIGS. 70 and 71 illustrate examples of cross-sectional structures during manufacturing steps of the memory device according to the second embodiment.

### DETAILED DESCRIPTION

In general, according to one embodiment, a memory device includes a first semiconductor, a first memory element, a first insulator, a first conductor, a second insulator, a second semiconductor, a second memory element, a third insulator, a second conductor, a fourth insulator, and a third conductor. The first memory element is in contact with a surface of the first semiconductor on a side of a first direction. The first insulator is on a surface of the first semiconductor on a side of a second direction crossing the first direction. The first conductor is on a surface of the first insulator on the side of the second direction. The second insulator is on a surface of the first semiconductor on a side of a third direction opposite to the second direction. The second semiconductor is located further in the third direction than the first semiconductor. The second memory element is in contact with a surface of the second semiconductor on the side of the first direction. The third insulator is on a surface of the second semiconductor on the side of the third direction. The second conductor is on a surface of the third insulator on the side of the third direction. The fourth insulator is on a surface of the second semiconductor on the side of the second direction. The third conductor is in contact with the second insulator and the fourth insulator.

Embodiments will now be described with reference to the figures. In order to distinguish components having substantially the same function and configuration in an embodiment or over different embodiments from each other, an additional numeral or letter may be added to the end of each reference numeral or letter. For an embodiment subsequent to an embodiment that has already been described, the description will concentrate mainly on the matters that constitute a difference from the already described embodiment. The entire description of a particular embodiment applies to another embodiment unless an explicit mention is made otherwise, or an obvious elimination is involved.

The figures are schematic, and the relation between the thickness and the area of a plane of a layer and the ratio of thicknesses of layers may differ from those in actuality. The figures may include components which differ in relations and/or ratios of dimensions in different figures.

Hereinafter, embodiments are described by using an xyz orthogonal coordinate system. An x axis extends in an x direction. A y axis extends in a y direction. A z axis extends in a z direction. A plus direction of a vertical axis in the drawings may be referred to as an upper side, and a minus direction as a lower side. A plus direction of a horizontal axis in the drawings may be referred to as a right side, and a minus direction as a left side. A side with a greater coordinate on the z axis is referred to as an upper side, and a side with a smaller coordinate as a lower side.

### 1. First Embodiment

### 1.1. Structure (Configuration)

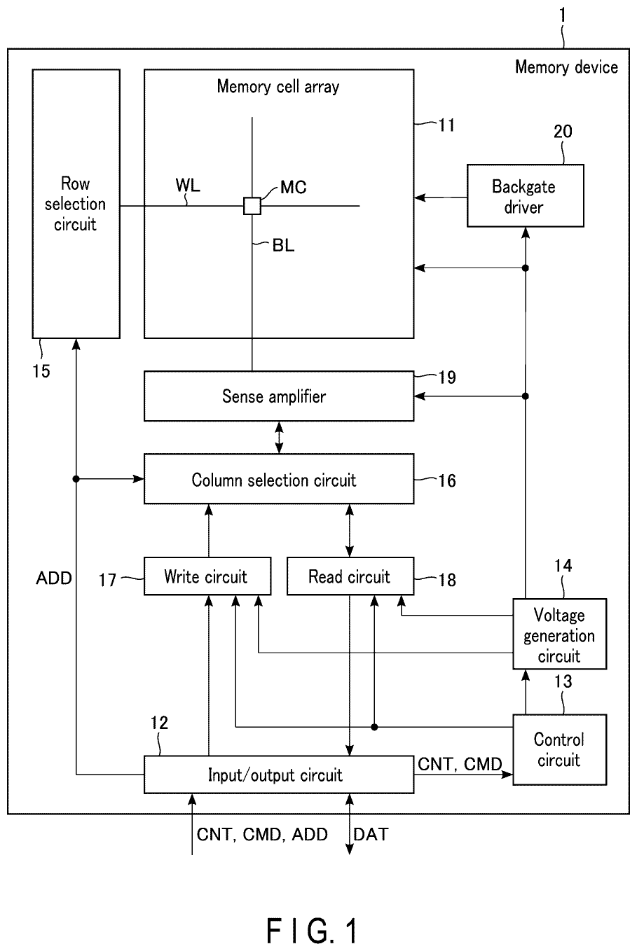

FIG. 1 shows functional blocks of a memory device according to a first embodiment. The memory device 1 is a device that stores data. As shown in FIG. 1, the memory device 1 includes a memory cell array 11, an input/output circuit 12, a control circuit 13, a voltage generation circuit 14, a row selection circuit 15, a column selection circuit 16, a write circuit 17, a read circuit 18, a sense amplifier 19, and a backgate driver 20.

The memory cell array 11 includes a plurality of memory cells MC, a plurality of word lines WL, and a plurality of bit lines BL. Each memory cell MC is capable of storing 1-bit data. Each memory cell MC is coupled to a single bit line BL and a single word line WL. The memory cell MC is coupled between the bit line BL and the plate line (not illustrated). The word line WL is associated with a row. The bit line BL is associated with a column. Through selection of a single row and a single column, a single memory cell MC is designated.

The input/output circuit 12 is a circuit that inputs and outputs data and signals. The input/output circuit 12 receives, from outside the memory device 1, e.g., from a memory controller, a control signal CNT, a command CMD, an address signal ADD, and data DAT. The input/output circuit 12 outputs data DAT. The data DAT is data to be written in the case of data writing in the memory device 1. The data DAT is read data in the case of data reading from the memory device 1.

The control circuit 13 is a circuit that controls the operation of the memory device 1. The control circuit 13 receives a command CMD and a control signal CNT from the input/output circuit 12. The control circuit 13 controls the write circuit 17 and the read circuit 18 based on control instructed by the command CMD and the control signal CNT.

The voltage generation circuit 14 is a circuit that generates various voltages used in the memory device 1. The voltage generation circuit 14 generates multiple voltages with different magnitudes under the control of the control circuit 13. The voltage generation circuit 14 supplies the generated voltages to the memory cell array 11, the write circuit 17, the read circuit 18, the sense amplifier 19, and the backgate driver 20.

The row selection circuit 15 is a circuit that selects a row of a memory cell MC. The row selection circuit 15 receives an address signal ADD from the input/output circuit 12. The row selection circuit 15 makes a single word line WL associated with a row designated by the received address signal ADD a selected state, using a voltage received from the voltage generation circuit 14.

The column selection circuit 16 is a circuit that selects a column of a memory cell MC. The column selection circuit 16 receives an address signal ADD from the input/output circuit 12. The column selection circuit 16 makes a bit line BL associated with a column designated by the received address signal ADD a selected state, using a voltage received from the voltage generation circuit 14.

The write circuit 17 is a circuit that performs control for writing data into the memory cells MC. The write circuit 17 receives data to be written from the input/output circuit 12. The write circuit 17 supplies, based on the control and data of the control circuit 13, the voltage received from the voltage generation circuit 14 to the column selection circuit 16.

The read circuit 18 is a circuit that performs control for reading data from the memory cells MC. The read circuit 18 supplies potentials received from the voltage generation circuit 14 to the column selection circuit 16. The read circuit supplies control signals for data reading to the sense amplifier 19.

The sense amplifier 19 is a circuit for determining data stored in the memory cell MC. The sense amplifier 19 includes a plurality of sense amplifier circuits. The sense amplifier 19 receives multiple voltages from the voltage generation circuit 14, and operates using the received voltages. During data reading, the sense amplifier 19 amplifies a potential of a bit line BL to determine data stored in the memory cell MC of a data read target. The determined data is supplied to the input/output circuit 12.

The backgate driver 20 is a circuit that controls a voltage applied to a backgate. The backgate is included in a transistor CT included in the memory cell MC, as will be described later. The backgate driver 20 applies a voltage received from the voltage generation circuit 14 to the backgate.

### 1.1.1. Memory Cells

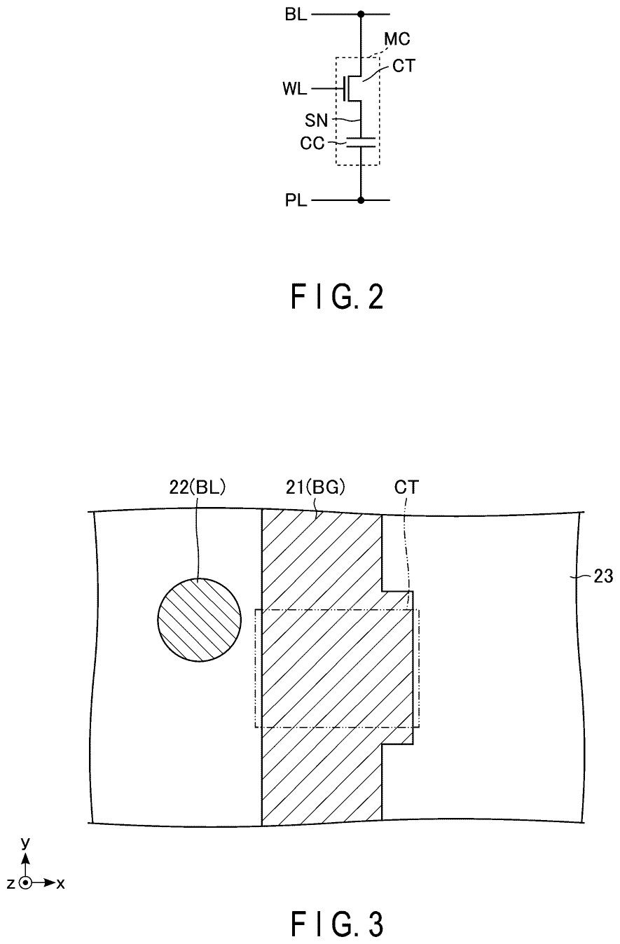

FIG. 2 shows components of the memory cell of the memory device according to the first embodiment and coupling of the components. Hereinafter, one of a source and a drain of a transistor may be referred to as one end of the transistor, and the other of the source and the drain may be referred to as the other end of the transistor.

As shown in FIG. 2, each memory cell MC includes a memory element CC and an n-type metal-oxide-semiconductor field-effect transistor (MOSFET) CT. Examples of the memory element CC include a capacitor and a ferroelectric element. The description below is based on an example in which the memory element CC is a capacitor CC.

The capacitor CC is coupled to, at one end, a plate line PL, and is coupled to, at another end, one end of the transistor CT. The capacitor CC stores data using a charge stored in a node coupled to the transistor CT. A node of the capacitor CC that is coupled to the transistor CT may be hereinafter referred to as a “storage node SN”.

The transistor CT is coupled to, at the other end, a single bit line BL, and is coupled to, at its gate, a single word line WL.

### 1.1.2. Memory Cell Array

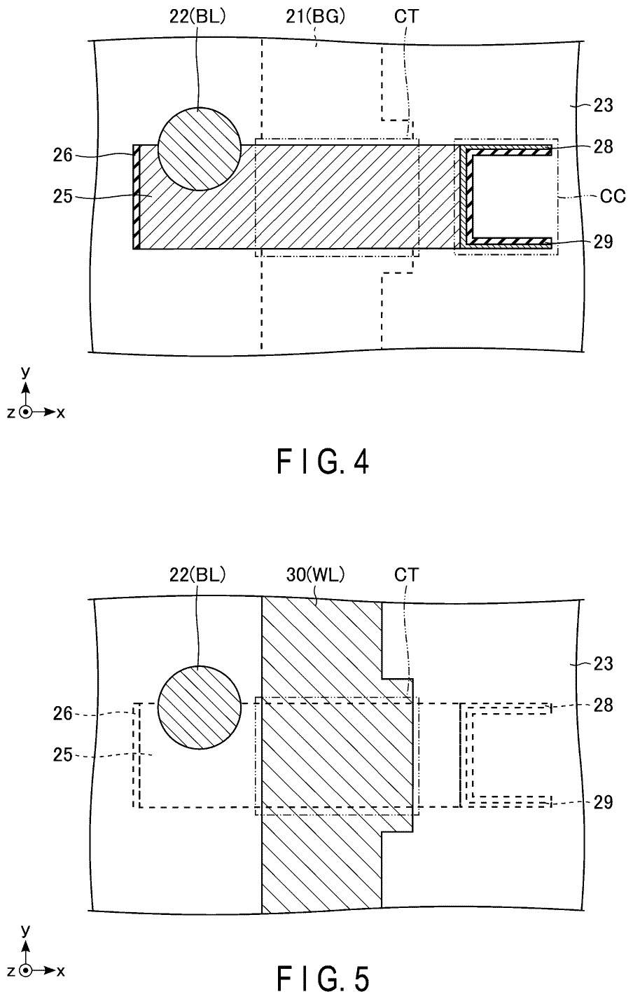

FIG. 3 to FIG. 5 are plan views of a part of the memory cell array of the memory device according to the first embodiment. FIG. 3 to FIG. 5 illustrate the same region in regard to an xy plane. FIG. 4 illustrates a region further in the z direction than a region illustrated in FIG. 3. FIG. 5 illustrates a region further in the z direction than the region illustrated in FIG. 4.

As illustrated in FIG. 3, the memory device 1 includes a conductor 21, a conductor 22 and an insulator 23. The conductor 21 extends along the y axis. A schematic shape of the conductor 21 along the xy plane is a quadrangular shape extending along the y axis. The conductor 21 includes a projecting portion on the right side. The conductor 21 functions as a backgate of a plurality of transistors CT. A part of the conductor 21 is included in one transistor CT. In one example, the conductor 21 includes tungsten.

The conductor 22 has a circular shape along the xy plane. The conductor 22 is located on the left side of the conductor 21. The conductor 22 functions as at least a part of one bit line BL. In one example, the conductor 22 includes tungsten.

The insulator 23 surrounds the conductors 21 and 22. In one example, the insulator 23 includes silicon oxide.

As illustrated in FIG. 4, the memory device 1 further includes a semiconductor 25, a gate insulator 26, an electrode 28 and a dielectric 29.

The semiconductor 25 extends along the x axis. In one example, the semiconductor 25 has a quadrangular shape. The semiconductor 25 intersects with the conductor 21. A portion of the semiconductor 25 which intersects with the conductor 21 functions as a part of the transistor CT, and functions as a region where a channel is formed. The semiconductor 25 includes silicon, and contains a dopant. A part of the semiconductor 25 is penetrated by the conductor 22. The semiconductor 25 is in contact with the conductor 22 at the part penetrated by the conductor 22.

The gate insulator 26 is in contact with a left end of the semiconductor 25. In one example, the gate insulator 26 includes silicon oxide.

The electrode 28 is a conductor that forms a part of the capacitor CC. The electrode 28 is in contact with a right end of the semiconductor 25. The electrode 28 has a shape similar to a U shape, and has a shape formed of three sides, adjacent two of which are connected. The electrode 28 opens on the right side.

The dielectric 29 is a dielectric that forms a part of the capacitor CC. The dielectric 29 is located in the inside of the electrode 28, and has a shape along the shape of the electrode 28. Specifically, the dielectric 29 has a shape similar to a U shape, and has a shape formed of three sides, adjacent two of which are connected. The dielectric 29 opens on the right side. The dielectric 29 is in contact with the electrode 28.

The insulator 23 surrounds the semiconductor 25, gate insulator 26, electrode 28, and dielectric 29. The insulator 23 is buried in a region surrounded by the dielectric 29.

As illustrated in FIG. 5, the memory device 1 further includes a conductor 30.

The conductor 30 extends along the y axis. A schematic shape of the conductor 30 along the xy plane is a quadrangular shape extending along the y axis. The conductor 30 includes a projecting portion on the right side. In one example, the conductor 30 has a shape along the xy plane, which is the same as the shape of the conductor 21 along the xy plane. The conductor 30 functions as a word line WL, and functions as gate electrodes of a plurality of transistors CT. A part of the conductor 30 is included in one transistor CT. The conductor 30, together with the conductor 21, sandwiches the semiconductor 25. In one example, the conductor 30 includes tungsten.

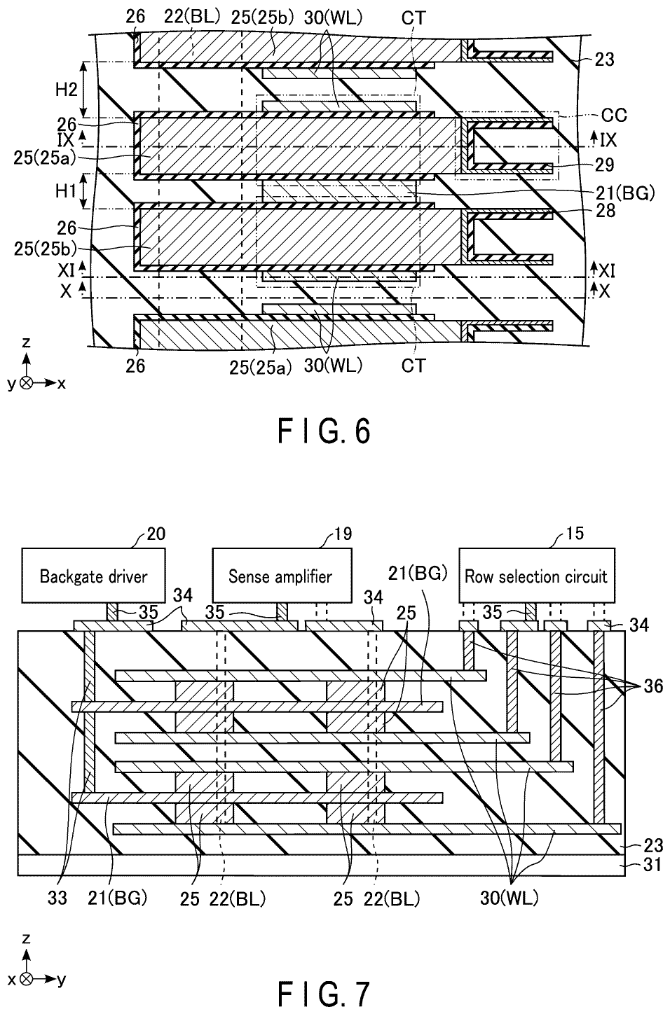

FIG. 6 illustrates an example of a cross-sectional structure of a part of the memory cell array of the memory device according to the first embodiment. FIG. 6 illustrates a cross section along the xz plane.

As illustrated in FIG. 6, above a substrate 31 (not illustrated), a plurality of semiconductors 25 are arranged at intervals. The semiconductors 25 include a plurality of pairs of semiconductors 25. The pairs are arranged along the z axis. Each pair includes two mutually neighboring semiconductors 25a and 25b. The semiconductors 25a and 25b have an interval H1 along the z axis. A pair of semiconductors 25a and 25b and another pair of semiconductors 25a and 25b have an interval H2. The interval H2 is greater than the interval H1.

Each gate insulator 26 covers an upper surface, a lower surface, and a left side surface of one semiconductor 25. In one example, each gate insulator 26 is continuous over an area of an upper surface, an area of a left side surface and an area of a lower surface of one semiconductor 25. Individual gate insulators 26 may be provided on the upper surface and on the lower surface of each semiconductor 25. A right end of each gate insulator 26 has an interval from the capacitor CC. In a region of the interval, the upper surface and lower surface of the semiconductor 25 are not covered by the gate insulator 26.

The conductor 21 is located between the two semiconductors 25 that are spaced apart by the interval H1. An upper surface of the conductor 21 is in contact with a lower surface of the gate insulator 26 on the lower surface of the semiconductor 25a. A lower surface of the conductor 21 is in contact with an upper surface of the gate insulator 26 on the upper surface of the semiconductor 25b. The conductor 21 functions as a backgate of the transistor CT including a part of the semiconductor 25a, and as a backgate of the transistor CT including a part of the semiconductor 25b. Specifically, the conductor 21 is shared by two transistors CT arranged along the z axis.

Each conductor 30 is located on that side of one semiconductor 25, which is opposite to the conductor 21. Specifically, a certain conductor 30 is located on the gate insulator 26 on the upper surface of the semiconductor 25a. Another conductor 30 is located on the gate insulator 26 on the lower surface of the semiconductor 25b. The two opposed conductors 30 have an interval.

### 1.1.3. Memory Cell Array

FIG. 7 illustrates an example of a cross-sectional structure of a part of the memory device according to the first embodiment. FIG. 7 illustrates an example in which each backgate receives an identical voltage. FIG. 7 schematically illustrates the row selection circuit 15, sense amplifier 19 and backgate driver 20. As described above with reference to FIG. 6 and as illustrated in FIG. 7, the structure composed of two semiconductors 25 (25a and 25b) arranged along the z axis, with the conductor 21 interposed therebetween, is repeatedly provided along the z axis. Although FIG. 7 illustrates an example in which two such structures are arranged along the z axis, three or more structures may be arranged along the z axis.

As illustrated in FIG. 7, the memory device 1 further includes a substrate 31, conductive plugs 33, conductors 34, and conductive plugs 35 and 36.

One of the conductor 21 and the conductor 30 extends, on one side, further than the other of the conductor 21 and the conductor 30. FIG. 7 illustrates one example. In the example illustrated in FIG. 7, a left end of the conductor 21 is located further on the left side than a left end of the conductor 30, and a right end of the conductor 30 is located further on the right side than a right end of the conductor 21. A right end of a conductor 30 that is located on a lower side is located further on the right side than a right end of a conductor 30 that is located on an upper side. Specifically, when the conductors 30 are viewed from above, a right end of a conductor 30 that is located on a lower side is exposed without being covered by another conductor 30.

The substrate 31, in one example, includes silicon. The structure described above with reference to FIG. 3 to FIG. 6 is located on an upper surface of the substrate 31.

Each plug 33, at a lower surface thereof, is in contact with an upper surface of a portion including a left end of one conductor 21 (or a portion near the left end). Further, each plug 33 excluding the uppermost plug 33, at an upper surface thereof, is in contact with a lower surface of a portion including a left end of another conductor 21. The uppermost plug 33 is coupled to the backgate driver 20 via the conductor 34 and plug 35.

Each plug 36, at a lower surface thereof, is in contact with an upper surface of a portion including a right end of one conductor 30 (or a portion near the right end). Each plug 36 is coupled to the row selection circuit 15 via the conductor 34 and plug 35.

The conductor 22 is coupled to the sense amplifier 19 via the conductor 34 and plug 35.

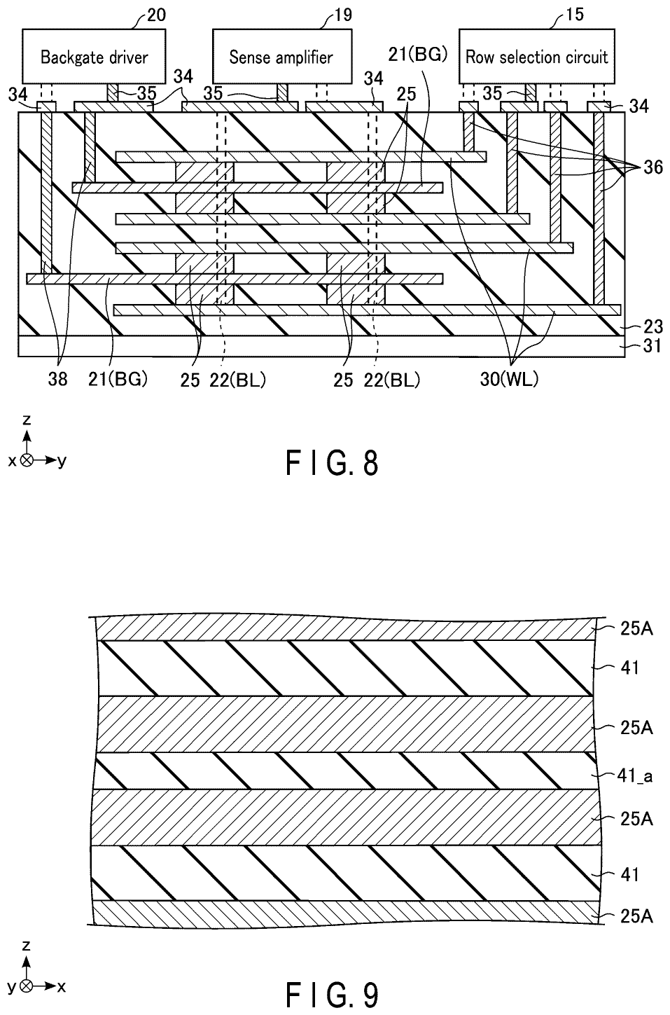

FIG. 8 illustrates an example of a cross-sectional structure of a part of the memory device according to the first embodiment. FIG. 8 illustrates an example in which the respective backgates can receive different voltages. In this example, unlike the example of FIG. 7, a left end of a conductor 21 that is located on a lower side is located further on the left side than a left end of a conductor 21 that is located on an upper side. Specifically, when the conductors 21 are viewed from above, a left end of a conductor 30 that is located on a lower side is exposed without being covered by another conductor 21.

The memory device 1 includes conductive plugs 38 in place of the plugs 33 in the example of FIG. 7. Each plug 38, at a lower surface thereof, is in contact with an upper surface of a portion including a left end of one conductor 21 (or a portion near the left end). Each plug 38 is coupled to the backgate driver 20 via the conductor 34 and plug 35. The plugs 38 are coupled to nodes in the backgate driver 20, which are capable of applying different voltages, via the conductors 34 and plugs 35, and the plugs 38 can receive the different voltages.

### 1.2. Manufacturing Method

FIG. 9 to FIG. 63 illustrate examples of cross-sectional structures during manufacturing steps of a part of the memory device according to the first embodiment.

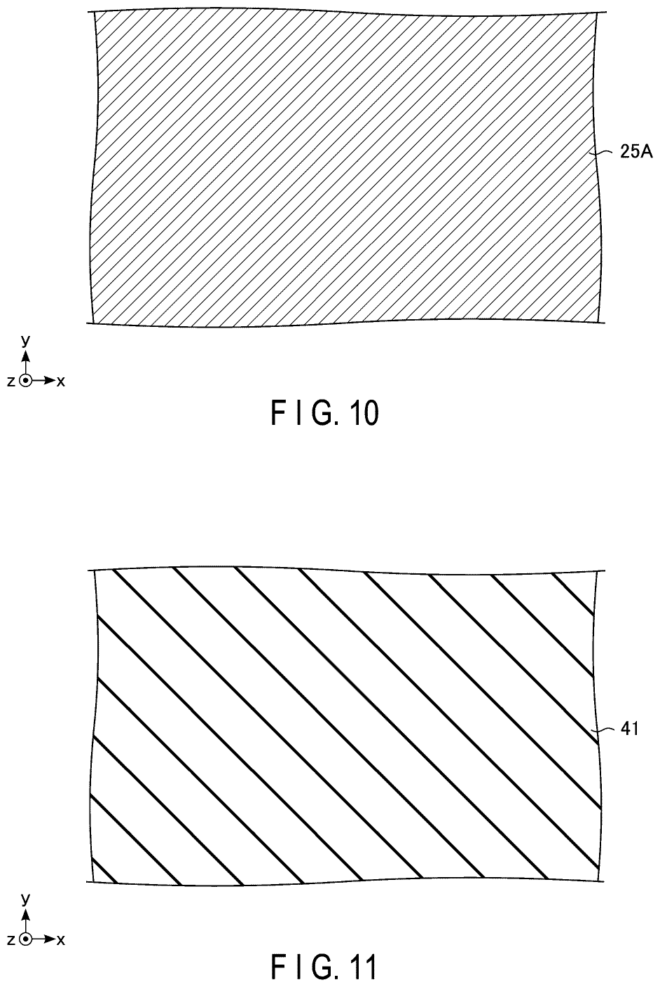

FIG. 9 illustrates the region illustrated in FIG. 6. FIG. 10 illustrates a region along line IX-IX in FIG. 6. FIG. 11 illustrates a region along line X-X in FIG. 6.

As illustrated in FIG. 9 to FIG. 11, a plurality of semiconductors 25A and a plurality of sacrificial members 41 are alternately deposited above the substrate 31 (not illustrated). Examples of the method of deposition include epitaxial growth.

The semiconductors 25A are components that are formed into semiconductors 25 in subsequent steps. The semiconductors 25A are formed by epitaxial growth in an atmosphere including an element functioning as a dopant.

The sacrificial members 41 include a sacrificial member 41_a. The sacrificial member 41_a is thinner than the sacrificial member 41. Each of the sacrificial members 41 excluding the sacrificial member 41_a has a thickness that is equal to the interval H2. The sacrificial member 41_a has a thickness that is equal to the interval H1.

The sacrificial members 41 include SiGe. Thereby, the semiconductor 25A on the upper surface of the sacrificial member 41 can have a crystalline structure conforming with a crystalline structure of the semiconductor 25A on the lower surface of the sacrificial member 41.

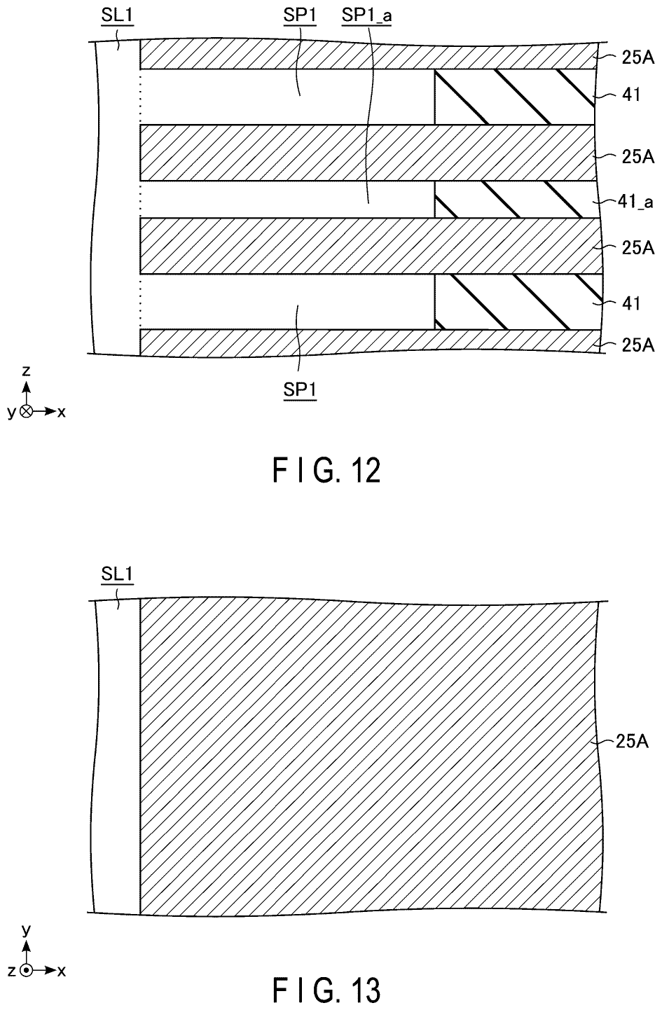

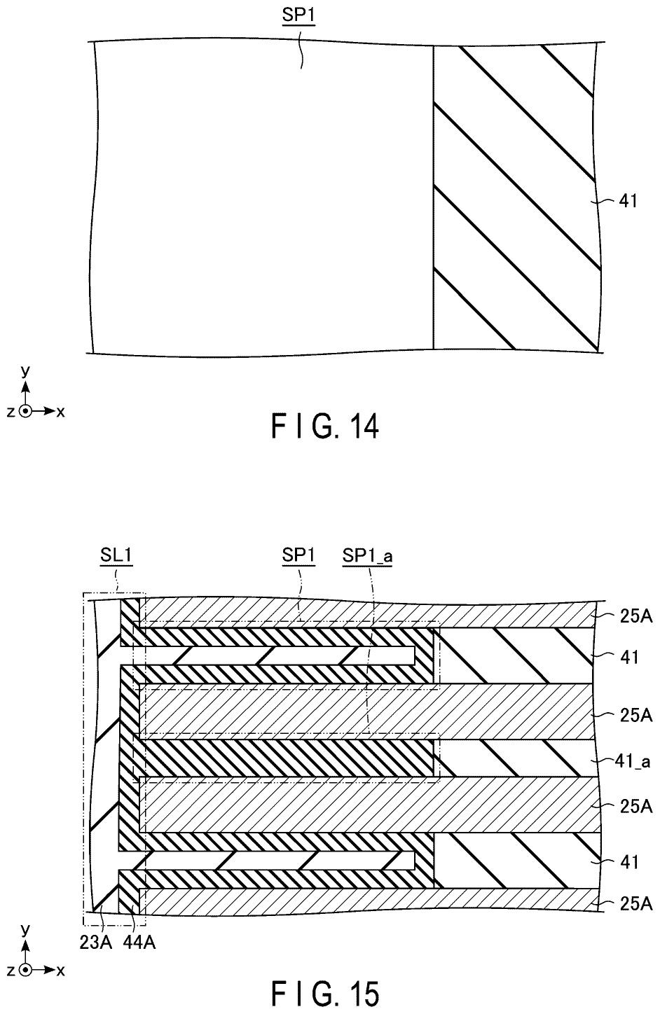

FIG. 12 illustrates the region illustrated in FIG. 6. FIG. 13 illustrates the region along line IX-IX in FIG. 6. FIG. 14 illustrates the region along line X-X in FIG. 6.

As illustrated in FIG. 12 to FIG. 14, a slit SL1 is formed by partly removing the semiconductors 25A and sacrificial members 41. The slit SL1 extends along the yz plane. The slit SL1 penetrates the semiconductors 25A and sacrificial members 41. A right end of the slit SL1 is in contact with an area in which the left end of the semiconductor 25 is to be formed. Examples of the method of forming the slit SL1 includes reactive ion etching (RIE).

Spaces SP1 are formed by partly removing the sacrificial members 41. Examples of the method of forming include wet etching. A chemical solution of the wet etching reaches a surface (i.e., a left end) of the sacrificial member 41 from the slit SL1, and retreats the surface of the sacrificial member 41 in a direction away from the slit SL1. The surface of the sacrificial member 41 is retreated slightly to the right side from an area where the right end of the gate insulator 26 is to be located. By the formation of the space SP1, a part of the upper surface of the semiconductor 25A and a part of the lower surface of the semiconductor 25A are exposed. The spaces SP1 include a space SP1_a. The space SP1_a is located in an area where a part of the sacrificial member 41 was located.

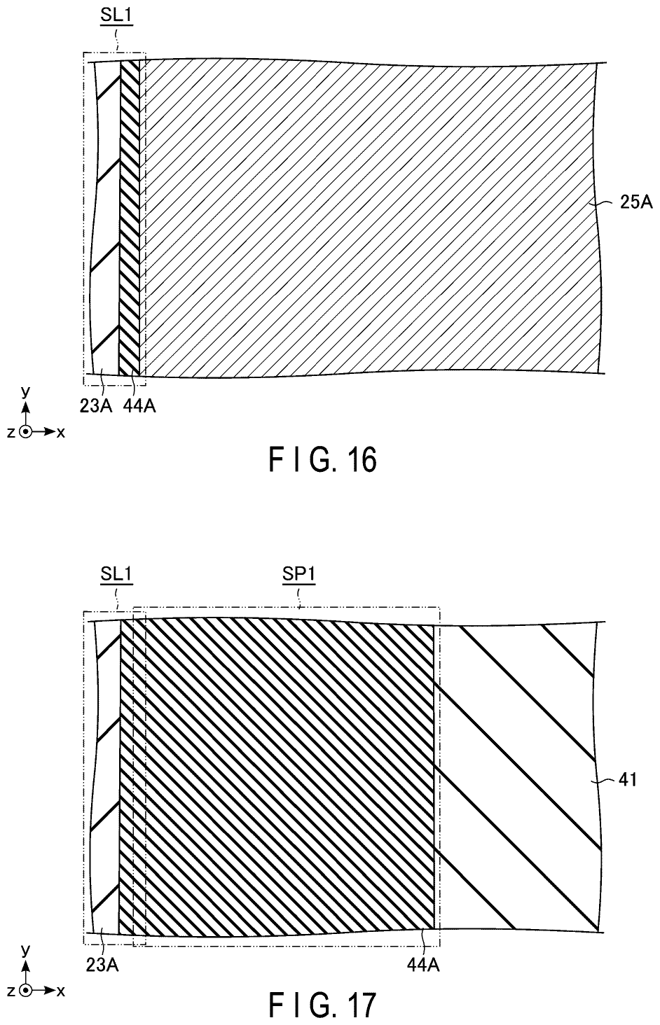

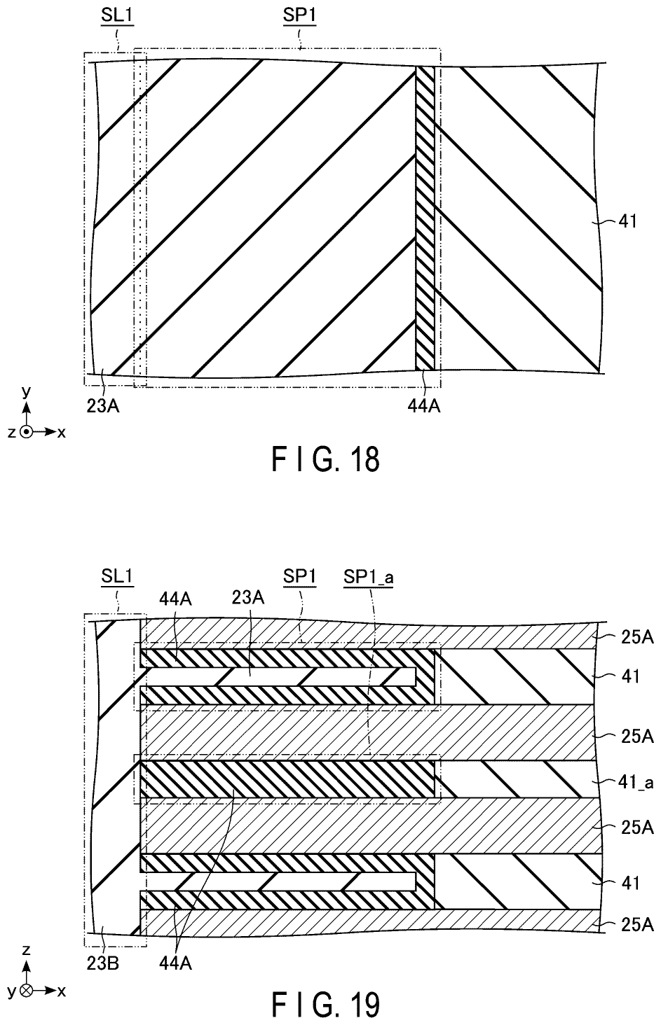

FIG. 15 illustrates the region illustrated in FIG. 6. FIG. 16 illustrates the region along line IX-IX in FIG. 6. FIG. 17 illustrates the region along line X-x in FIG. 6. FIG. 18 illustrates a region along line XI-XI in FIG. 6.

As illustrated in FIG. 15 to FIG. 18, a sacrificial member 44A is formed. The sacrificial member 44A includes silicon nitride. Examples of the method of forming the sacrificial member 44A include chemical vapor deposition (CVD). The sacrificial member 44A covers a surface of the semiconductor 25A exposed in the slit SL1, and a surface of the semiconductor 25A exposed in the space SP1. The sacrificial member 44A is continuous over the area on the surface of the semiconductor 25A exposed in the slit SL1 and the space SP1, and the area on the surface of the semiconductor 25A exposed in the space SP1. The sacrificial member 44A is buried in the space SP1_a.

An insulator 23A is buried in a region in the slit SL1, where the sacrificial member 44A is not located, and in a region in the space SP1, where the sacrificial member 44A is not located. An example of the insulator 23A includes silicon oxide. The insulator 23A forms a part of the insulator 23. Examples of the method of forming the insulator 23A include CVD.

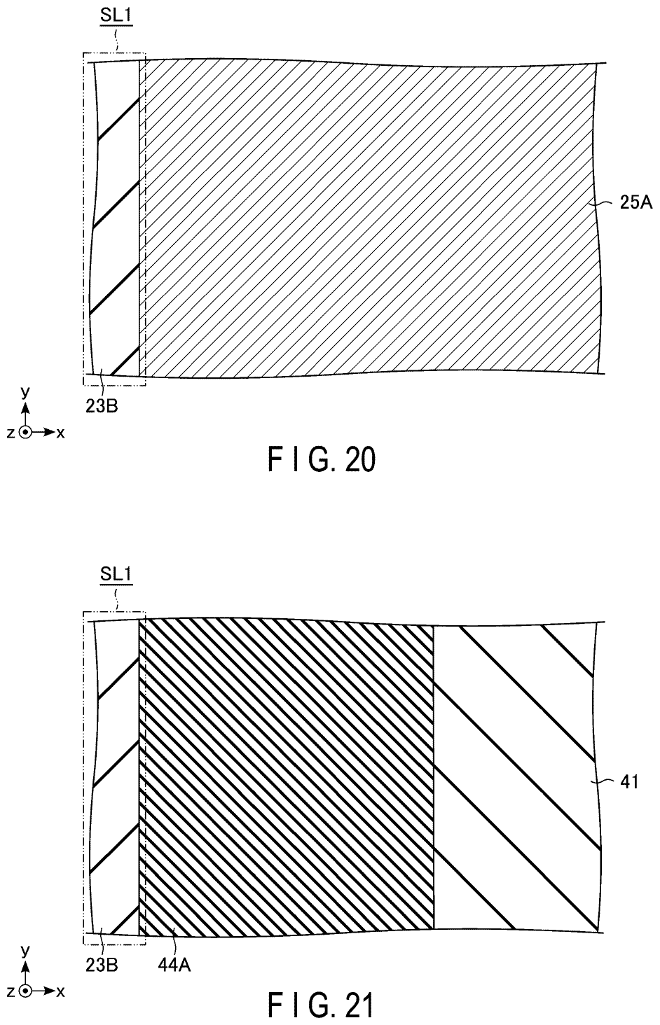

FIG. 19 illustrates the region illustrated in FIG. 6. FIG. 20 illustrates the region along line IX-IX in FIG. 6. FIG. 21 illustrates the region along line X-X in FIG. 6.

As illustrated in FIG. 19 to FIG. 21, a part of the insulator 23A which is located in the slit SL1 and a part of the sacrificial member 44A which is located in the slit SL1 are removed. Examples of the method of removing include RIE. As a result of the removing, the insulator 23A and the sacrificial member 44A remain in the space SP1. As a result of the removing, the slit SL1 is formed once again. Then, an insulator 23B is buried in the slit SL1. Examples of the insulator 23B include silicon oxide. The insulator 23B forms a part of the insulator 23.

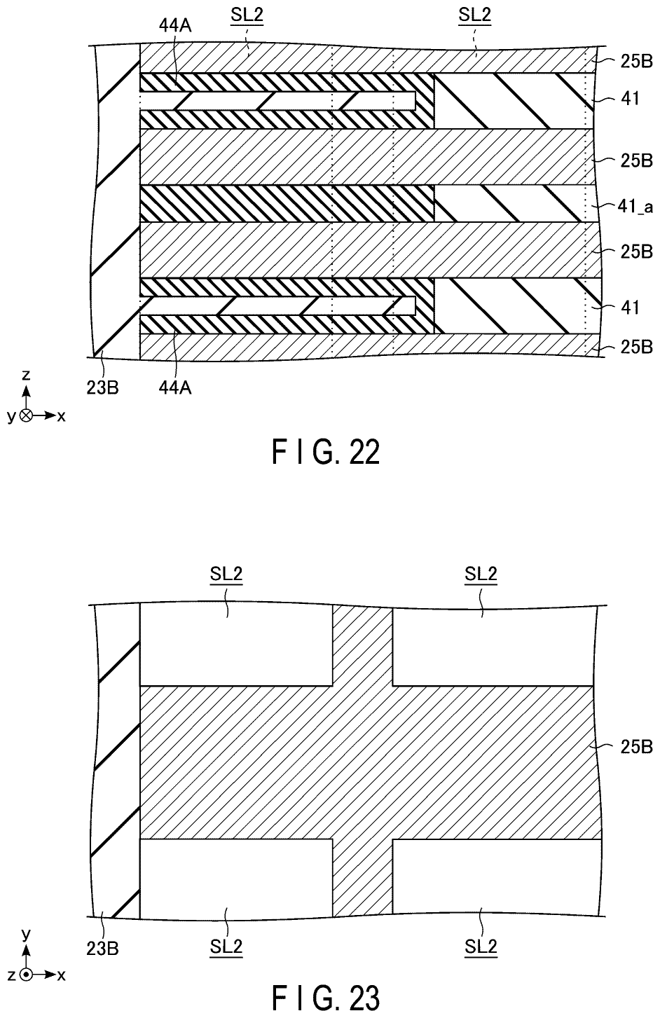

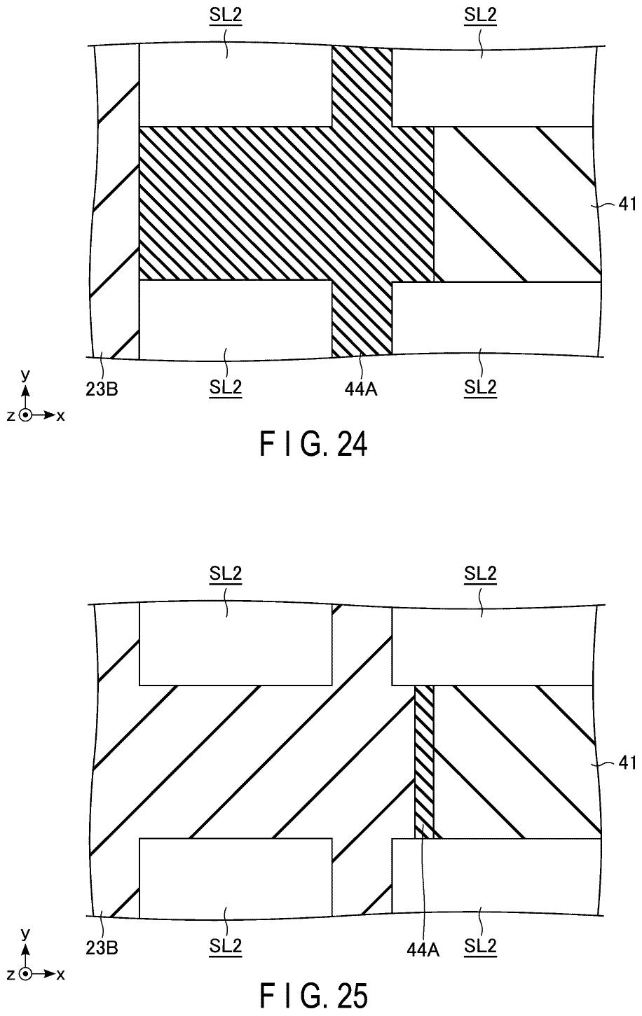

FIG. 22 illustrates the region illustrated in FIG. 6. FIG. 23 illustrates the region along line IX-IX in FIG. 6. FIG. 24 illustrates the region along line X-X in FIG. 6. FIG. 25 illustrates the region along line XI-XI in FIG. 6.

As illustrated in FIG. 22 to FIG. 25, slits SL2 are formed by removing parts of the sacrificial members 41, parts of the semiconductors 25A, parts of the sacrificial members 44A, and a part of the insulator 23A. The slits SL2 penetrate the sacrificial members 41, semiconductors 25A, sacrificial members 44A and insulator 23A along the z axis. Some slits SL2 are arranged with an interval along the x axis on a y-directional side of an area of the semiconductors 25 in a plane along the xy plane. Other slits SL2 are arranged with an interval along the x axis on a −y directional side of and areas of the semiconductors 25.

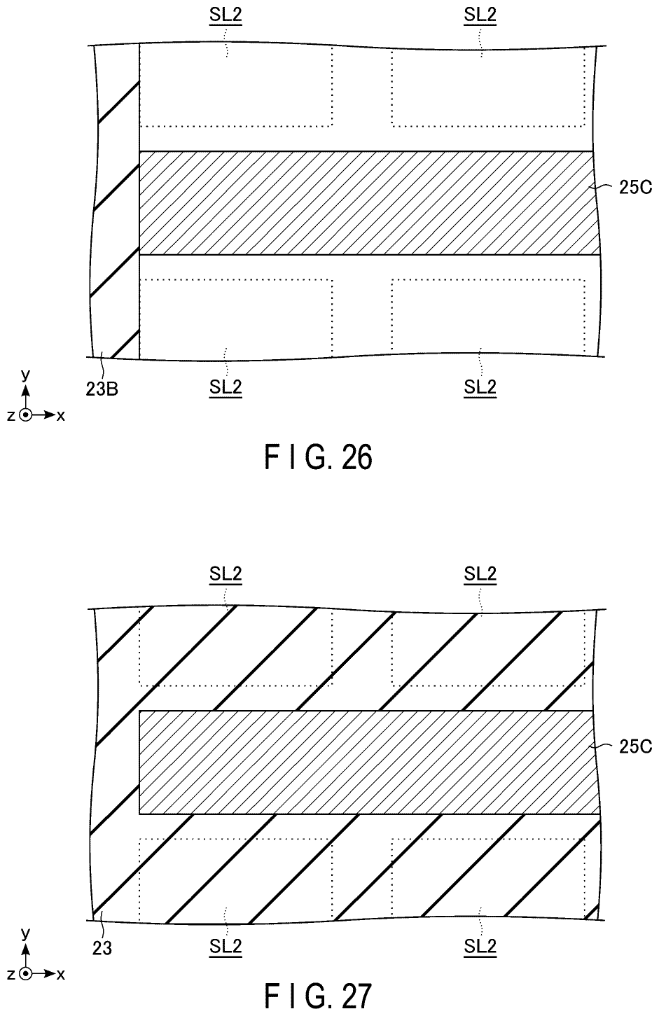

FIG. 26 illustrates the region along line IX-IX in FIG. 6. As illustrated in FIG. 26, the semiconductor 25B is partly removed, and thereby the semiconductors 25B are formed into semiconductors 25C. Examples of the method of removing includes RIE. A gas of RIE reaches the semiconductors 25B in the slits SL2, and removes surfaces of the semiconductors 25B. The semiconductors 25C have a substantially linear shape along the x axis. The length along the y axis of the semiconductors 25C are substantially equal to the length along the y axis of the semiconductors 25. Depending on the positions and shapes of the slits SL2, the surface on the y directional side and the surface on the −y directional side of the semiconductors 25B may not be linear along the x axis, but may include a projecting portion between the slits SL2.

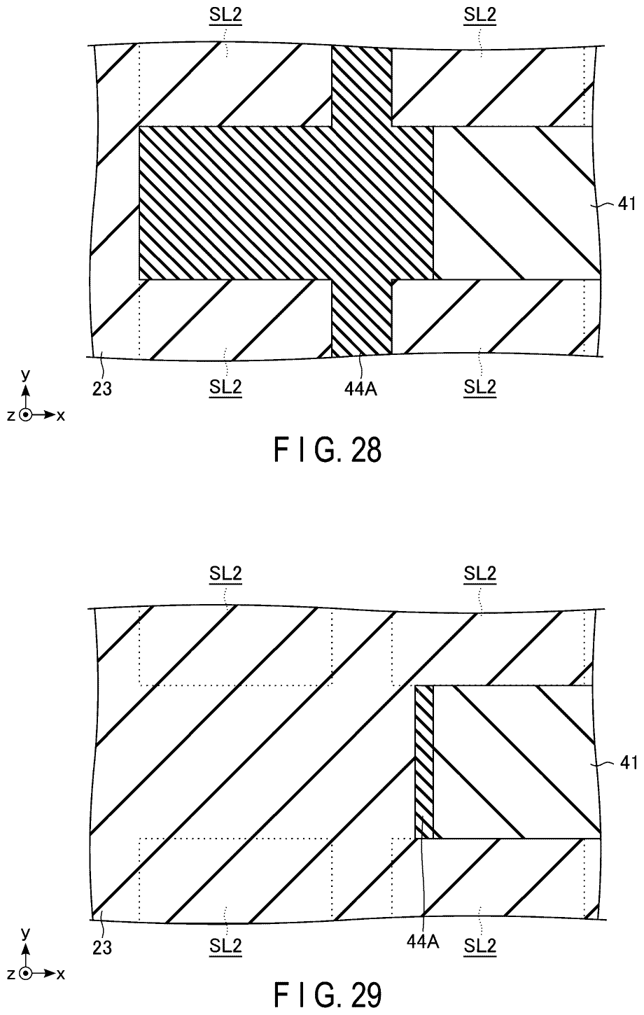

FIG. 27 illustrates the region along line IX-IX in FIG. 6. FIG. 28 illustrates the region along line X-X in FIG. 6. FIG. 29 illustrates the region along line XI-XI in FIG. 6.

As illustrated in FIG. 27 to FIG. 29, an insulator 23 is buried in the slits SL2. The insulator 23B is connected to the buried insulator 23.

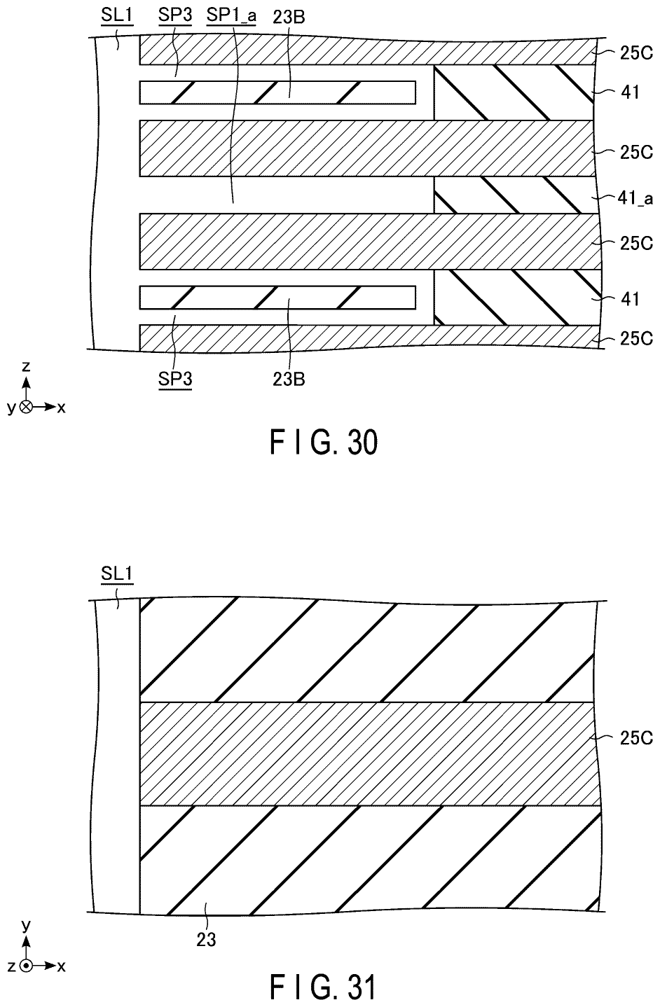

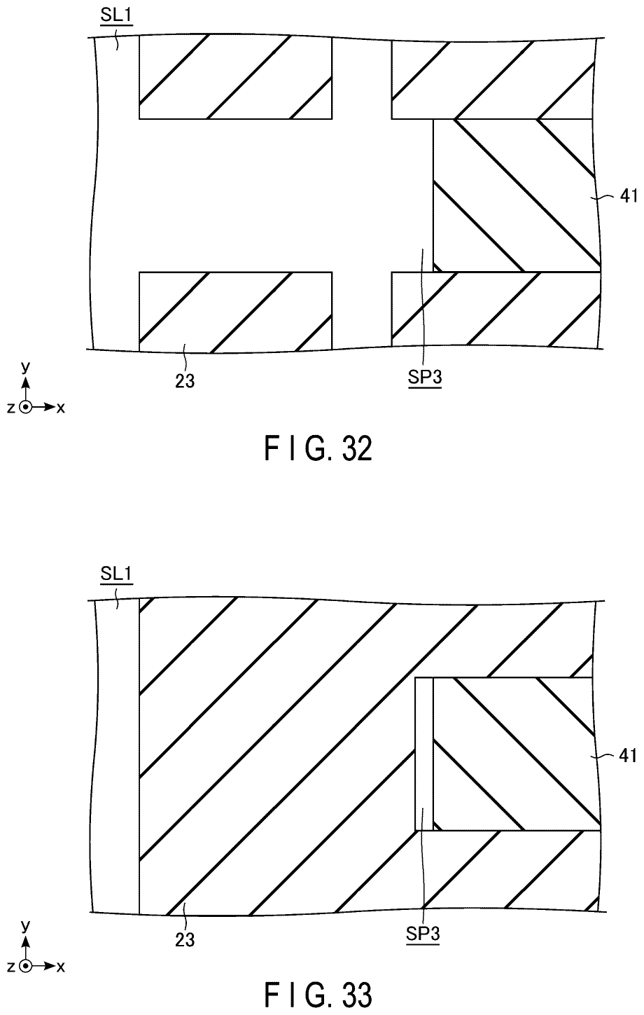

FIG. 30 illustrates the region illustrated in FIG. 6. FIG. 31 illustrates the region along line IX-IX in FIG. 6. FIG. 32 illustrates the region along line X-X in FIG. 6. FIG. 33 illustrates the region along line XI-XI in FIG. 6.

As illustrated in FIG. 30 to FIG. 33, a part of the insulator 23B which is located in the slit SL1 is removed. Examples of the method of removing include RIE. By the removing, the slit SL1 is formed once again.

The sacrificial members 44A is removed. Examples of the method of removing include wet etching. A chemical solution of wet etching reaches the surfaces of the sacrificial members 44A from the slit SL1. By removing the sacrificial members 44A, spaces SP3 are formed around the insulators 23B. By removing the sacrificial members 44A, the space SP1_a is formed once again. The surface of each semiconductor 25C is exposed at a portion in the slit SL1, at a portion facing the space SP3, and at a portion facing the space SP1_a.

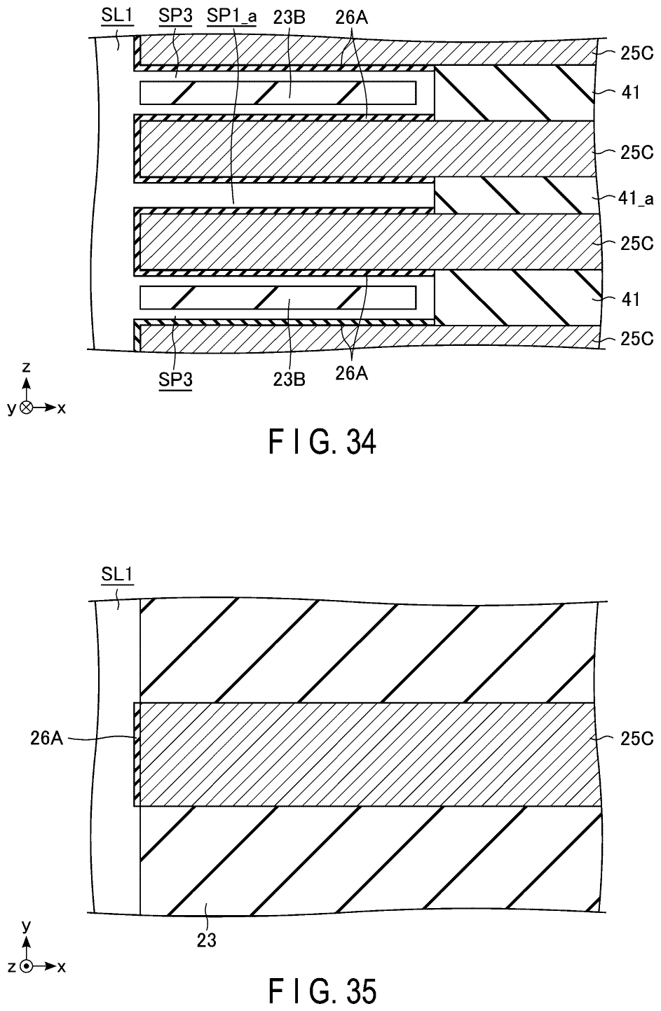

FIG. 34 illustrates the region illustrated in FIG. 6. FIG. 35 illustrates the region along line IX-IX in FIG. 6.

As illustrated in FIGS. 34 and 35, a gate insulators 26A are formed on the exposed portions of the surface of the semiconductors 25C. The gate insulators 26A are elements that are subsequently formed into the gate insulators 26. Examples of the method of forming the gate insulators 26A include thermal oxidation.

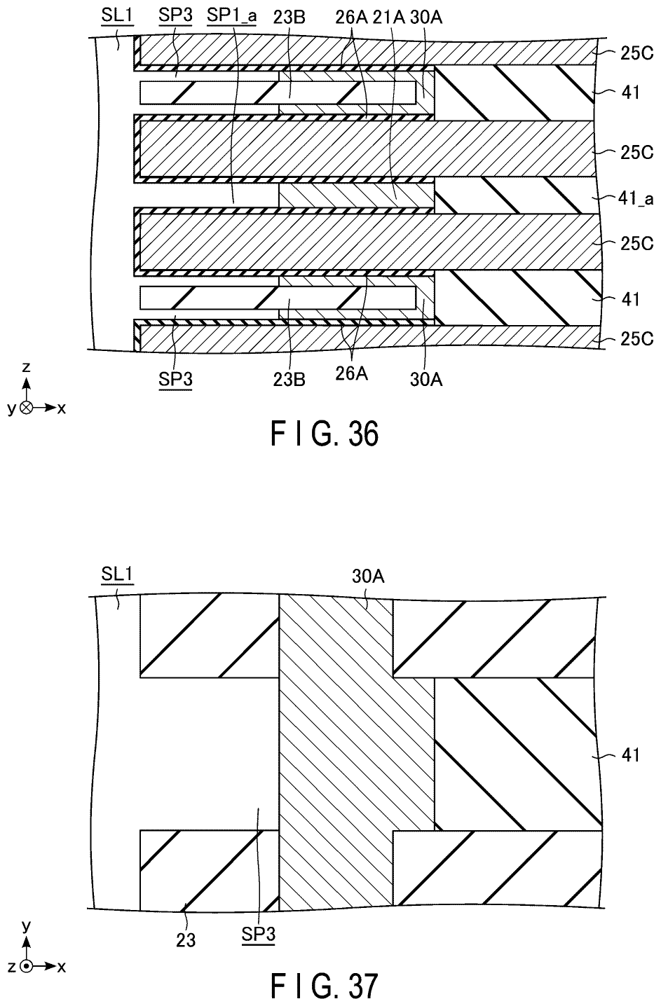

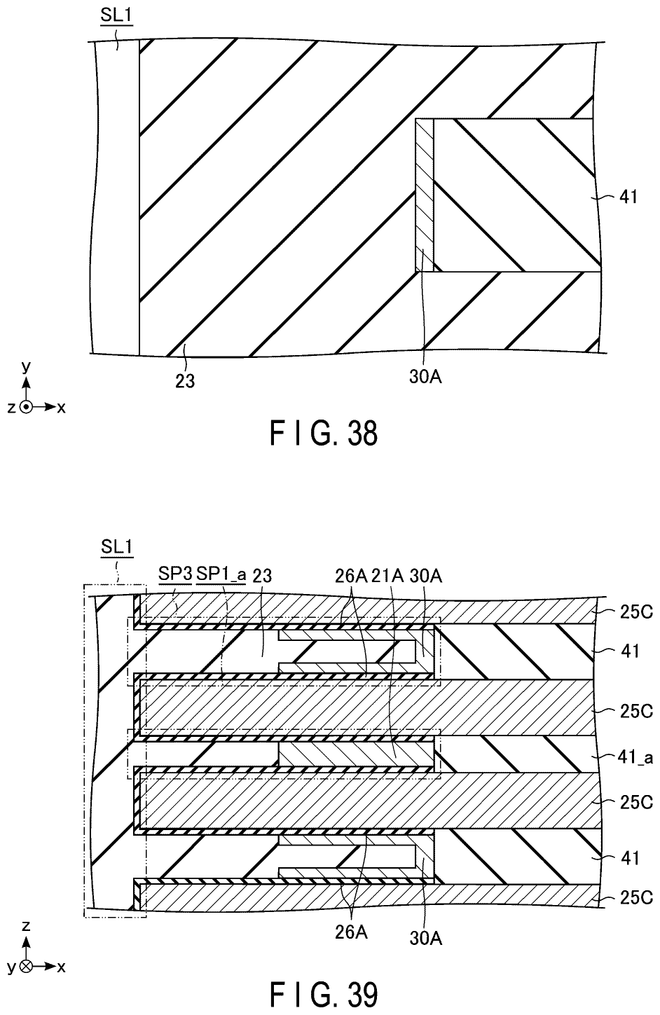

FIG. 36 illustrates the region illustrated in FIG. 6. FIG. 37 illustrates the region along line X-X in FIG. 6. FIG. 38 illustrates the region along line XI-XI in FIG. 6.

As illustrated in FIG. 36 to FIG. 38, a conductor 21A is buried in the space SP1_a, and conductors 30A are buried in the space SP3. The conductor 21A is an element that is subsequently formed into the conductor 21. The conductors 30A are components that are subsequently formed into the conductors 30. Examples of the method of forming the conductors 21A and 30A include CVD.

A part of the conductor 21A is removed, and parts of the conductors 30A are removed. Example of the method of removing include wet etching. A chemical solution of wet etching reaches the surface of the conductor 21A and the surfaces of the conductor 30A from the slit SL1. By the wet etching, the surface of the conductor 21A and the surfaces of the conductors 30A retreat in a direction away from the slit SL1. The left end of the conductor 21A is retreated to a position at which the left end of the conductor 21 is to be located. The left ends of the conductors 30A are retreated to positions at which the left ends of the conductors 30 are to be located. By the partial removal of the conductor 21A, a part of the space SP1_a is formed once again. By the partial removal of the conductors 30A, parts of the spaces SP3 are formed once again.

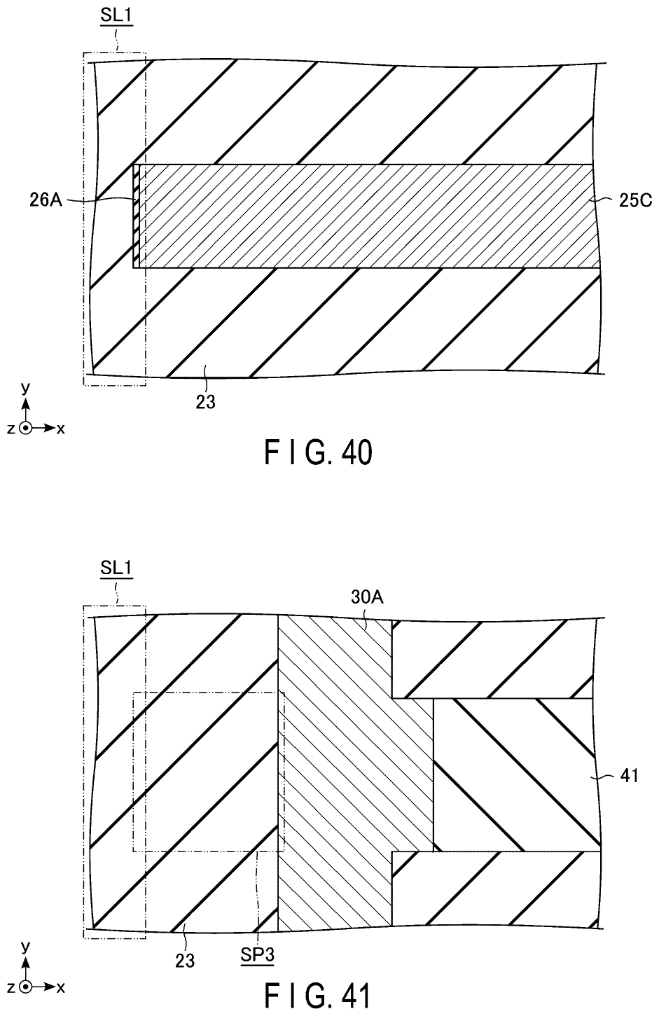

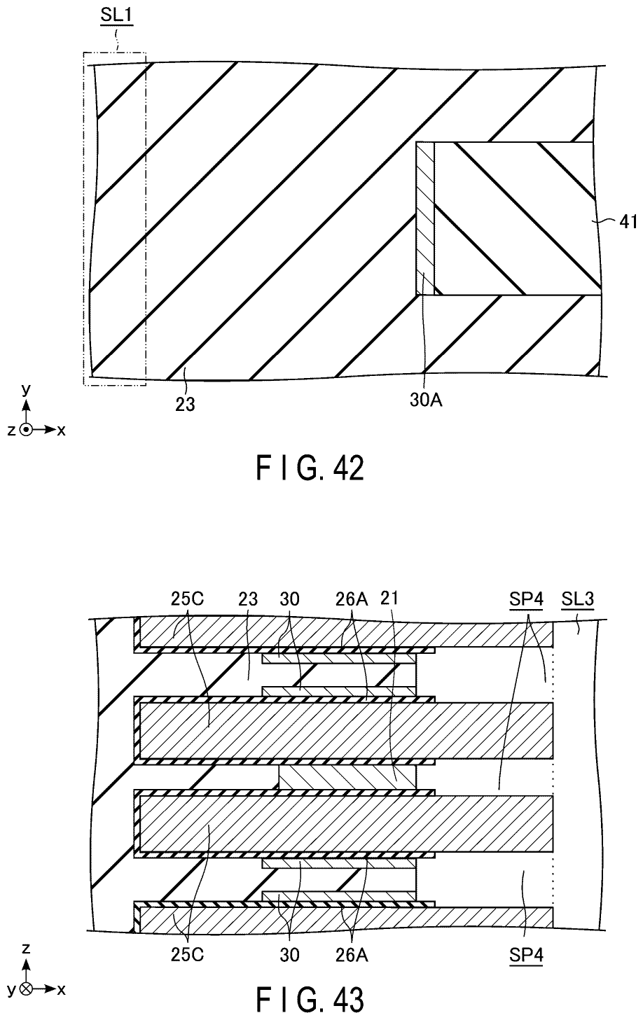

FIG. 39 illustrates the region illustrated in FIG. 6. FIG. 40 illustrates the region along line IX-IX in FIG. 6. FIG. 41 illustrates the region along line X-X in FIG. 6. FIG. 42 illustrates the region along line XI-XI in FIG. 6.

As illustrated in FIG. 39 to FIG. 42, an insulator 23 is buried in the slit SL1. In addition, the insulator 23 is buried in an area in the space SP3 in which the gate insulator 26A and conductor 30A are not buried and in an area in the space SP1_a in which the gate insulator 26A and conductor 21A are not buried. Examples of the method of burying include CVD.

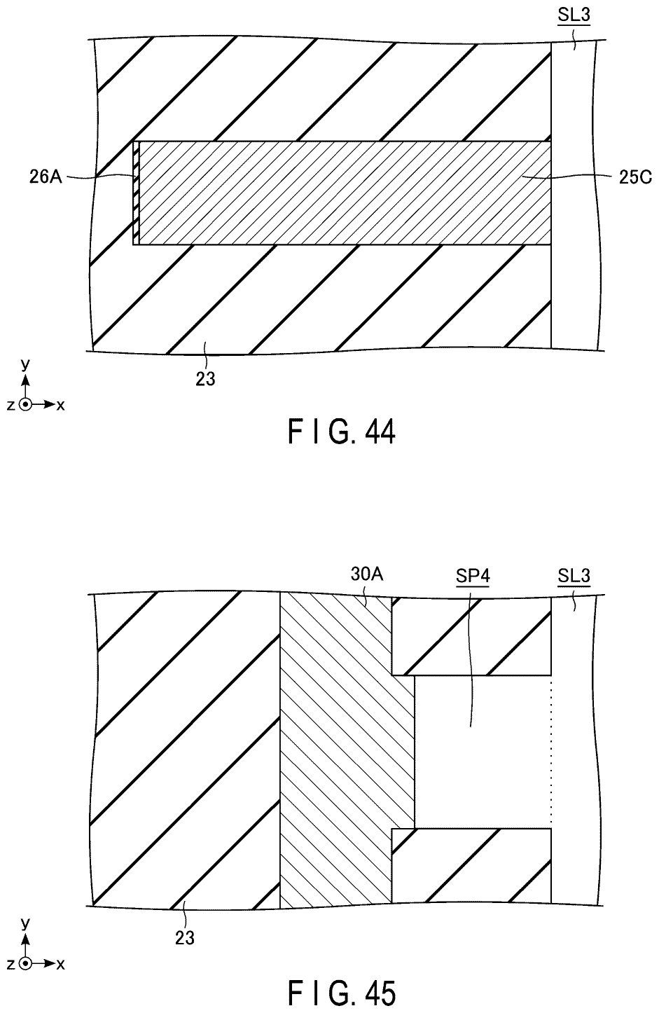

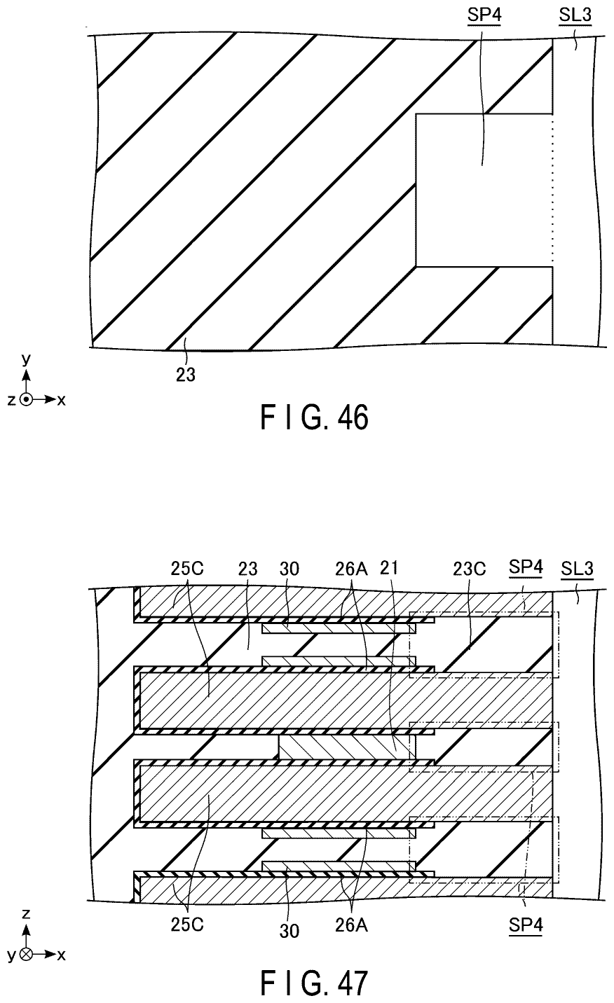

FIG. 43 illustrates the region illustrated in FIG. 6. FIG. 44 illustrates the region along line IX-IX in FIG. 6. FIG. 45 illustrates the region along line X-X in FIG. 6. FIG. 46 illustrates the region along line XI-XI in FIG. 6.

As illustrated in FIG. 43 to FIG. 46, a slit SL3 is formed. The slit SL3 extends along the yz plane. The slit SL3 penetrates the semiconductors 25C and sacrificial members 41. A left end of the slit SL3 is in contact with an area in which the capacitor CC is to be formed. Examples of the method of forming the slit SL3 include RIE.

Spaces SP4 are formed by removal of the sacrificial members 41 and by partial removal of the conductors 21A and 30A. Examples of the method of forming include wet etching. A chemical solution of wet etching reaches the surfaces of the sacrificial members 41 from the slit SL3, and retreats the surfaces of the sacrificial members 41 in a direction away from the slit SL3. The surfaces of the sacrificial members 41 are retreated until the right end of the conductor 21A and the right end of the conductor 30A are exposed.

Further, the exposed surfaces of the conductors 30A are retreated in a direction away from the slit SL3. By the progress of retreating, parts of the conductors 30A which extend along the z axis are removed. As a result, two parts of a conductor 30A which are interposed between the semiconductors 25C and the insulator 23 are separated, and the conductors 30 are formed. In addition, by the retreating of the right ends of the conductors 30A, the right end of the conductor 21A is also retreated, and the conductor 21A is formed into the conductor 21.

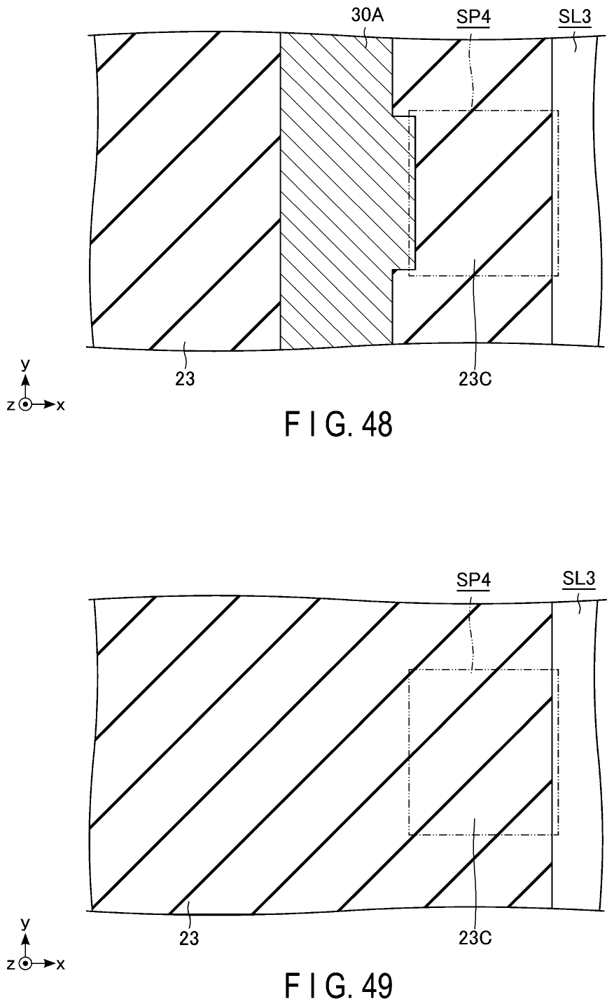

FIG. 47 illustrates the region illustrated in FIG. 6. FIG. 48 illustrates the region along line X-X in FIG. 6. FIG. 49 illustrates the region along line XI-XI in FIG. 6.

As illustrated in FIG. 47 to FIG. 49, an insulator 23C is buried in the spaces SP4. A part of the insulator 23C forms a part of the insulator 23. Examples of the method of burying the insulator 23C include CVD. A gas for CVD reaches the spaces SP4 from the slit SL3.

The insulator 23 remaining in the slit SL3 is removed. Thereby, parts of the surface of the semiconductor 25C is exposed in the slit SL3. Examples of the method of removing the insulator 23 include RIE. By the removing, the slit SL3 is formed once again.

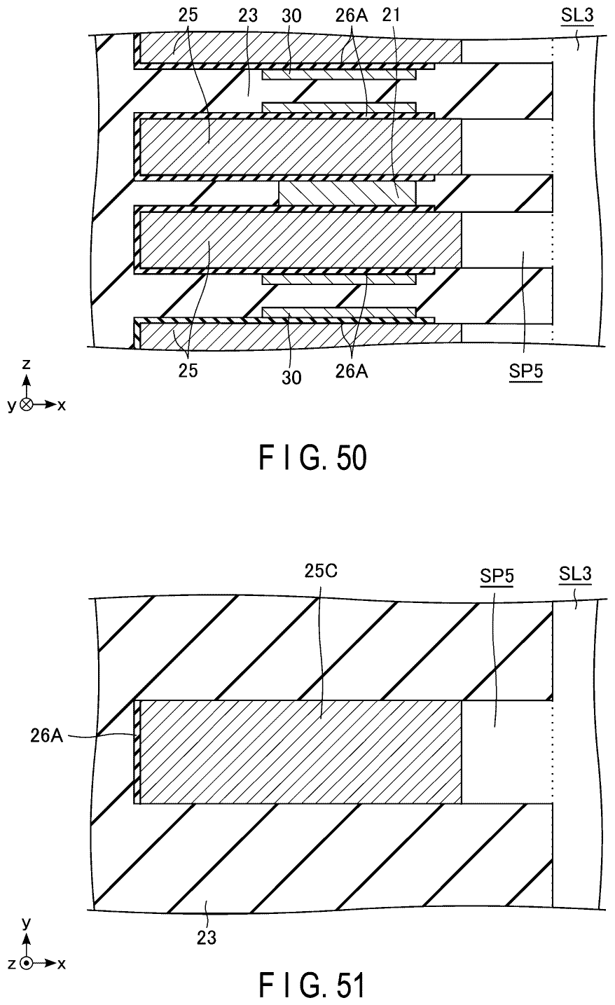

FIG. 50 illustrates the region illustrated in FIG. 6. FIG. 51 illustrates the region along line IX-IX in FIG. 6.

As illustrated in FIG. 50 and FIG. 51, spaces SP5 are formed by partly removing the semiconductors 25C. Examples of the method of forming include wet etching. A chemical solution of wet etching reaches the surfaces of the semiconductors 25C from the slit SL3, and retreats the surfaces of the semiconductors 25C in a direction away from the slit SL3. Thereby, the semiconductors 25 are formed.

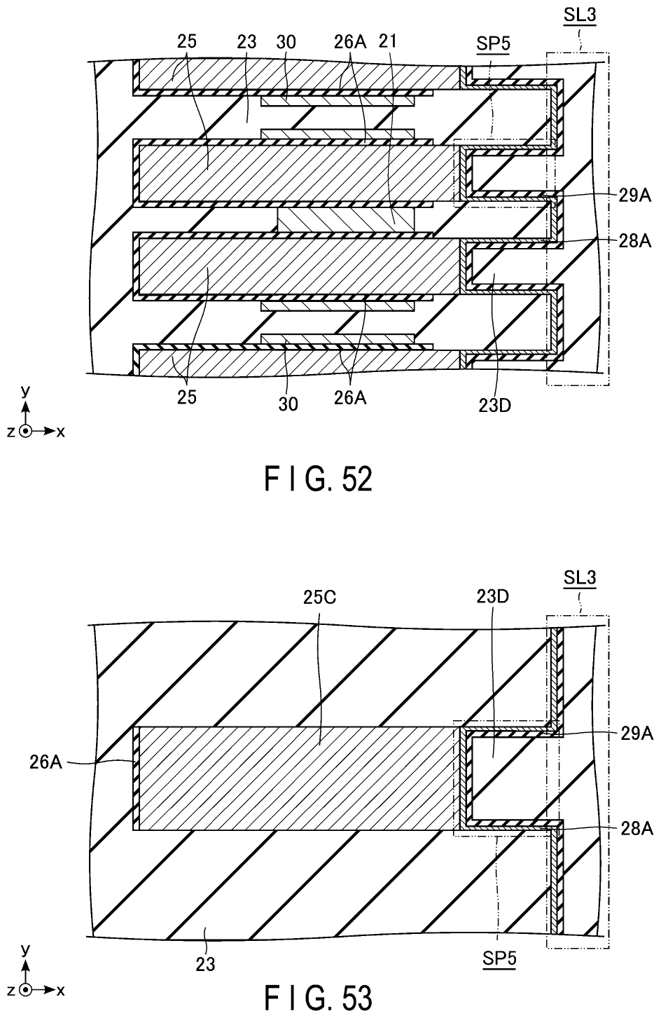

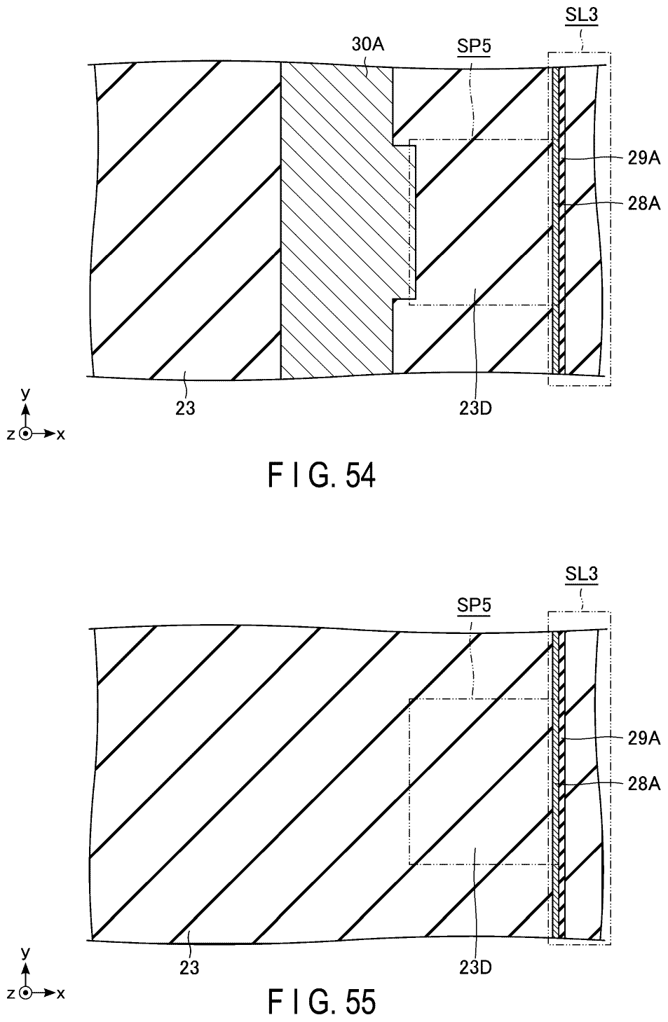

FIG. 52 illustrates the region illustrated in FIG. 6. FIG. 53 illustrates the region along line IX-IX in FIG. 6. FIG. 54 illustrates the region along line X-X in FIG. 6. FIG. 55 illustrates the region along line XI-XI in FIG. 6.

As illustrated in FIG. 52 to FIG. 55, an electrode 28A is deposited on the surface of the slit SL3 and on the surfaces of the spaces SP5. The electrode 28A covers right side surfaces of the semiconductors 25, portions of upper surfaces of the insulators 23 which are exposed in the space SP5, portions of right side surfaces of the insulator 23 which are exposed in the slit SL3, and portions of upper surfaces of the insulators 23 which are exposed in the space SP5. The electrode 28A is a component that is subsequently formed into the electrodes 28. Examples of the method of depositing the electrode 28A include CVD.

A dielectric 29A is deposited on the electrode 28A. The dielectric 29A is a component that is subsequently formed into the dielectrics 29. Examples of the method of depositing the dielectric 29A include CVD.

An insulator 23D is deposited on the dielectric 29A. A part of the insulator 23D forms a part of the insulator 23. The insulator 23D is buried in areas of the spaces SP5 in which the electrode 28A and dielectric 29A are not buried. The insulator 23D is buried in an area of the slit SL3 in which the electrode 28A and dielectric 29A are not buried. Examples of the method of depositing the insulator 23D include CVD.

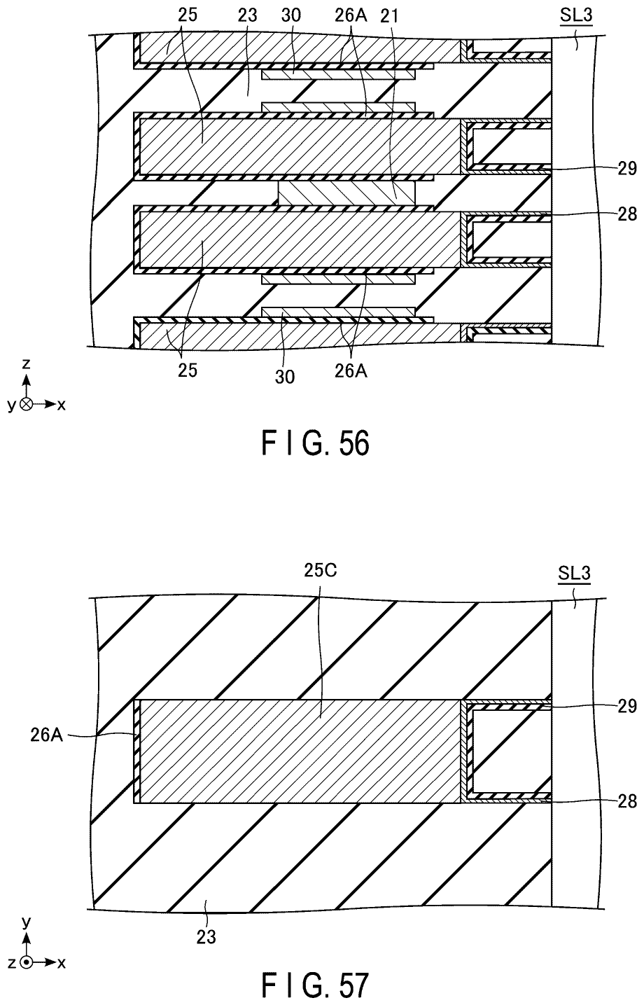

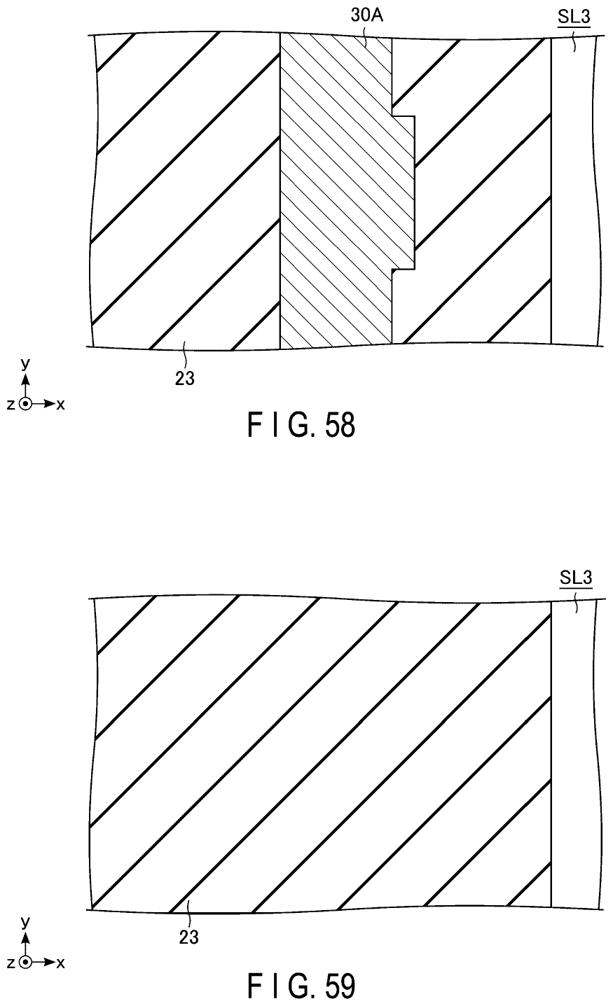

FIG. 56 illustrates the region illustrated in FIG. 6. FIG. 57 illustrates the region along line IX-IX in FIG. 6. FIG. 58 illustrates the region along line X-X in FIG. 6. FIG. 59 illustrates the region along line XI-XI in FIG. 6.

As illustrated in FIG. 56 to FIG. 59, portions of the electrode 28A which are located in the slit SL3, and portions of the dielectric 29A which are located in the slit SL3 are removed. Specifically, right side portions of the dielectric 29A which are located on the right side surfaces of the insulators 23 are removed. Then, portions of the electrode 28A which are located on the right side surfaces of the insulators 23 are removed. Examples of the method of partly removing the electrode 28A and dielectric 29A include RIE. By partly removing the electrode 28A and dielectric 29A, the electrode 28 and dielectric 29 are formed. By partly removing the electrode 28A and dielectric 29A, the slit SL3 is formed once again.

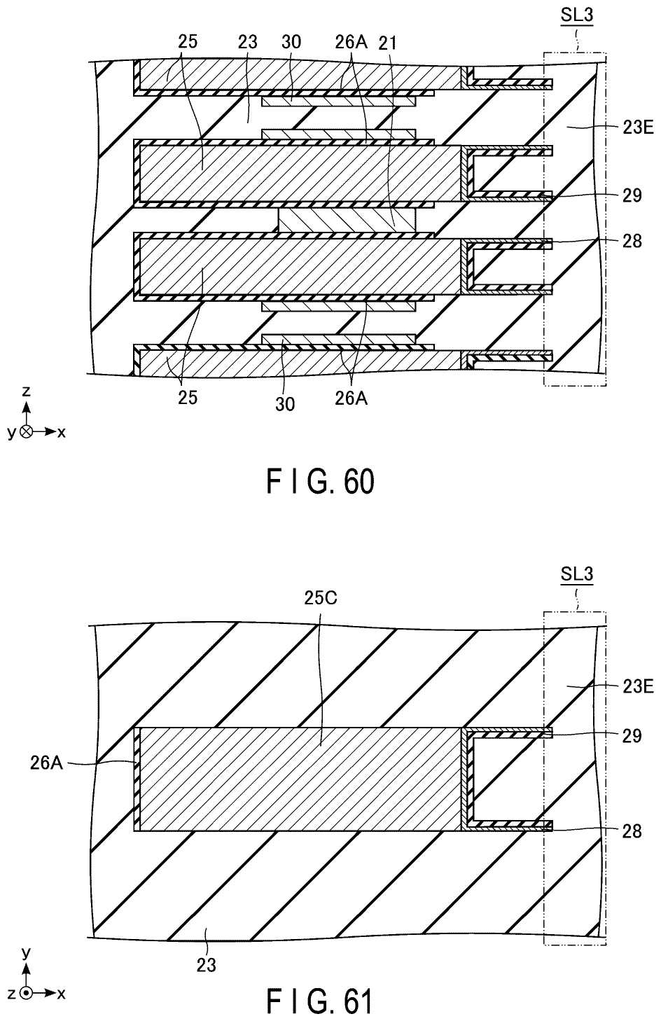

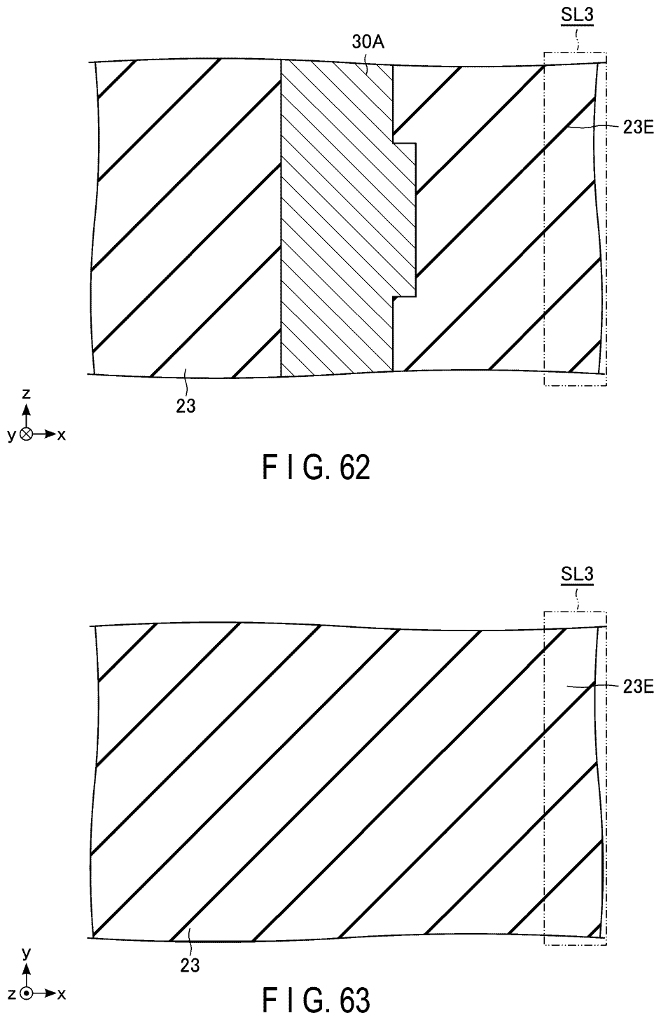

FIG. 60 illustrates the region illustrated in FIG. 6. FIG. 61 illustrates the region along line IX-IX in FIG. 6. FIG. 62 illustrates the region along line X-X in FIG. 6. FIG. 63 illustrates the region along line XI-XI in FIG. 6.

As illustrated in FIG. 60 to FIG. 62, by deposition of an insulator 23E, the slit SL3 is filled with the insulator 23E. The insulator 23E forms a part of the insulator 23. Methods of depositing the insulator 23E include CVD.

As illustrated in FIG. 3 to FIG. 6, the conductor 22 penetrating the semiconductors 25 and insulator 23 is formed.

### 1.3. Advantages (Advantageous Effects)

As described below, according to the first embodiment, a memory device including memory cells each having a small volume can be provided.

In a DRAM including three-dimensionally stacked memory cells, a potential of a word line of one of memory cells which neighbor each other along the z axis can unintendedly affect a potential of a body of a transistor of the other memory cell. To cope with this, it is known to form a transistor with a double-gate structure. Specifically, a semiconductor functioning as a body is sandwiched between a conductor functioning as a word line and another conductor. The another conductor functions as a backgate. By applying a voltage to the backgate, the potential of the body of a transistor of a certain memory cell is less affected by the potential of the word line of another memory cell.

A DRAM including memory cells including transistors of the double-gate structure uses, as a unit structure, a set of a semiconductor and conductors sandwiching the semiconductor, and can include the unit structures that are repeatedly provided along the z axis. An interval between semiconductors of mutually neighboring unit structures has a certain magnitude in order to secure an interval between a conductor functioning as a gate electrode and a conductor functioning as a backgate. Specifically, the interval of the semiconductors has the magnitude of the interval H2 in the example of FIG. 6. Thus, a transistor including a backgate has a greater volume than the volume of a transistor that does not include a backgate.

In the memory device of the first embodiment, the two transistors CT arranged along the z axis share the conductor 21 and have a symmetric structure along the xy plane. Specifically, a conductor 30 is provided on the upper surface of the semiconductor 25a via a gate insulator 26, a conductor 30 is provided on the lower surface of the semiconductor 25b via a gate insulator 26, and one conductor 21 is provided between the semiconductors 25a and 25b. Thus, the conductor 21 is not provided on each of the two semiconductors 25a and 25b. This can make the interval H1 between the semiconductors 25a and 25b smaller than the interval H2. Thus, the volume of the transistor CT is small, and, by extension, the volume of the memory cell MC is small.

Moreover, according to the first embodiment, the transistor CT has a double-gate structure. Thus, the potential of the body of the transistor CT of a certain memory cell MC is less affected by the potential of the word line WL of the transistor CT of another memory cell MC.

### 2. Second Embodiment

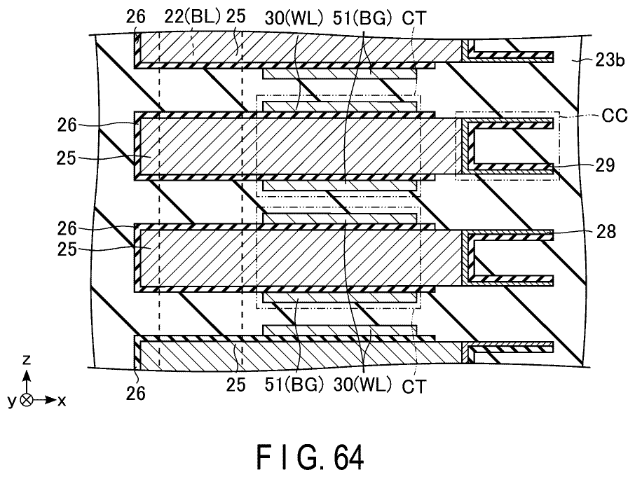

FIG. 64 illustrates an example of a cross-sectional structure of a part of a memory device according to a second embodiment. FIG. 64 illustrates a cross section along the xz plane.

As illustrated in FIG. 64, a memory device 1b of the second embodiment does not include the conductor 21. Instead, the memory device 1b includes a conductor 51.

The conductor 30 is provided on the upper surface of each semiconductor 25 via the gate insulator 26. The conductor 51 is provided on the lower surface of each semiconductor 25 via the gate insulator 26. The conductor 51 functions as a backgate of the transistor CT including a portion that the conductor 51 faces in the semiconductor 25.

Based on the fact that the memory device 1b does not include the conductor 21, the memory device 1b does not include a pair of semiconductors 25 that are spaced apart by the interval H1.

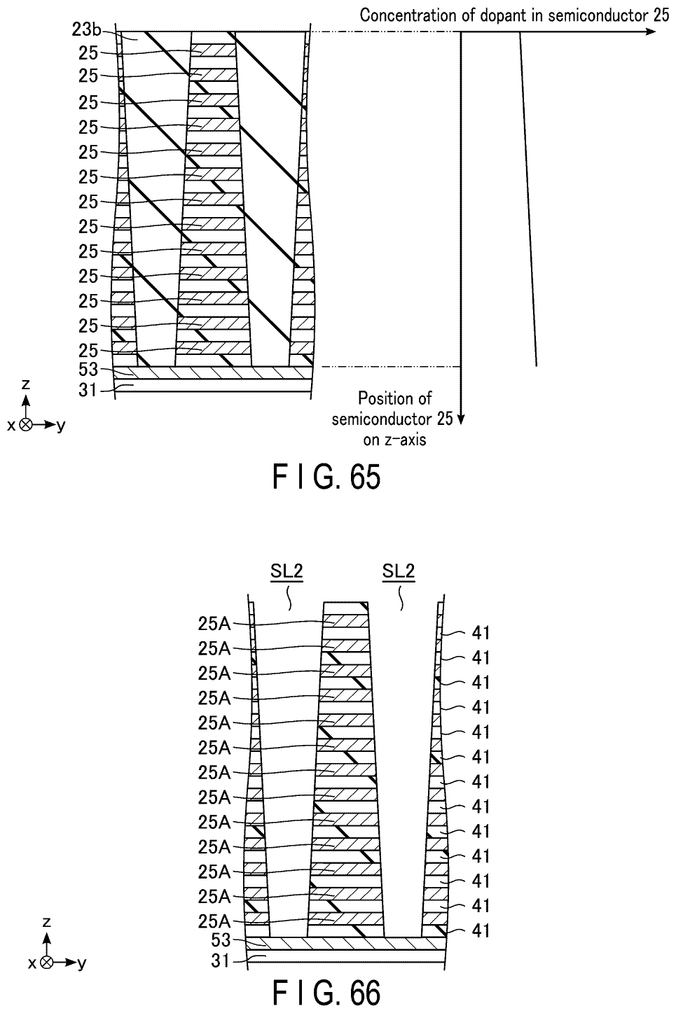

FIG. 65 illustrates an example of a relationship between semiconductors and concentrations of a dopant in the memory device according to the second embodiment. FIG. 65 also illustrates an example of a cross-sectional structure of a part of the memory device of the second embodiment. FIG. 65 illustrates a cross section along the yz plane. In FIG. 65, some components are omitted.

As illustrated in a left side part of FIG. 65, a semiconductor 53 is provided on the upper surface of the substrate 31. The semiconductor 53 includes the same material as the semiconductor 25, and includes, in one example, silicon.

Semiconductors 25 are arranged along the z axis at intervals above the semiconductor 53. A part of an insulator 23b is located between the semiconductors 25. A semiconductor 25 located on a higher level has a shorter length along the y axis.

As illustrated in a right side part of FIG. 65, the distribution of the concentrations of the dopant of the semiconductors 25 along the z axis corresponds to the distribution of the y-axis lengths of the semiconductors 25 along the z axis. Specifically, a semiconductor 25 located on a higher level contains a dopant of a lower concentration along the z axis. In other words, a semiconductor 25 having a smaller length along the y axis contains a dopant of a lower concentration. In one example, the concentration is an average concentration of a semiconductor 25 that is an object.

The shapes of the semiconductors 25 result from steps corresponding to the steps illustrated in FIG. 22 to FIG. 25 of the first embodiment. Specifically, as illustrated in FIG. 66, as a result of the step of forming the slit SL2 in the semiconductors 25A and sacrificial member 41, the slit SL2 has a taper shape. Specifically, the slit SL2 has a greater length along the y axis at a higher position.

The distribution of the concentrations of the dopant is formed in a step corresponding to the step illustrated in FIG. 9 to FIG. 11 of the first embodiment. Specifically, each semiconductor 25A is formed by epitaxial growth in the atmosphere including the dopant of a concentration that is to be contained in the semiconductor 25A.

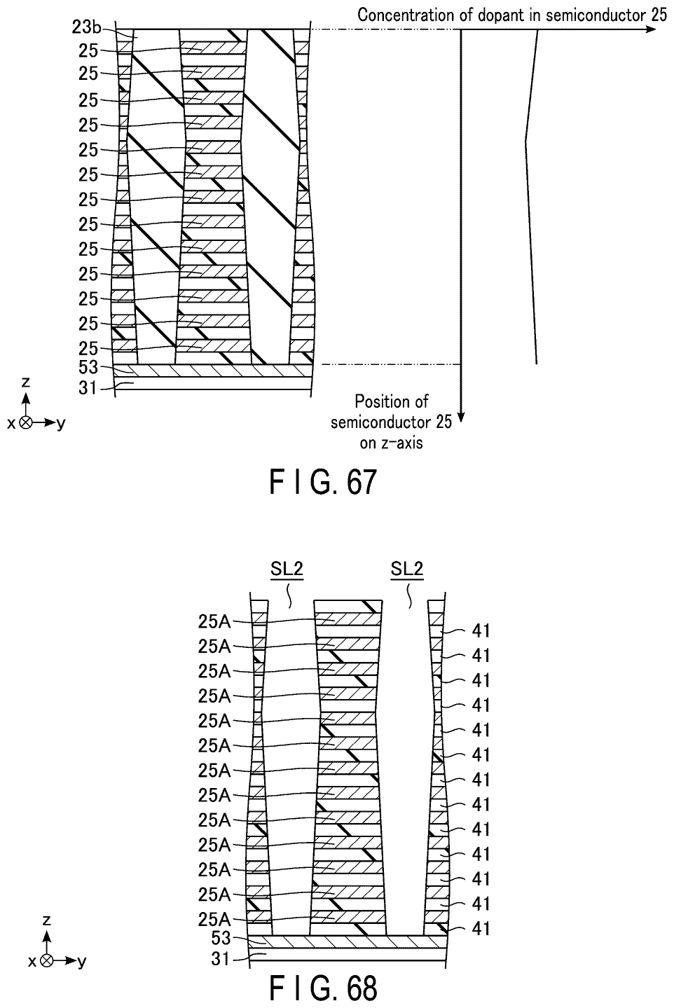

FIG. 67 illustrates another example of the relationship between the semiconductors and the concentrations of the dopant in the memory device according to the second embodiment. FIG. 67 also illustrates another example of the cross-sectional structure of a part of the memory device of the second embodiment. FIG. 67 illustrates a cross section along the yz plane. In FIG. 67, some structural elements are omitted.

As illustrated in a left side part of FIG. 67, a semiconductor 25 other than the lowermost and uppermost semiconductors 25 have the smallest length along the y axis. With respect to the uppermost semiconductor 25 as the semiconductor 25 having the greatest length along the y axis, a semiconductor 25 located at a lower level has a smaller length along the y axis. With respect to the lowermost semiconductor 25 as the semiconductor 25 having the greatest length along the y axis, a semiconductor 25 located at a higher level has a smaller length along the y axis.

As illustrated in a right side part of FIG. 67, the distribution of the concentrations of the dopant of the semiconductors 25 along the z axis corresponds to the distribution of the y-axis lengths of the semiconductors 25 along the z axis. In other words, a semiconductor 25 having a smaller length along the y axis contains a dopant of a lower concentration.

The shapes of the semiconductors 25 result from steps corresponding to the steps illustrated in FIG. 22 to FIG. 25 of the first embodiment. Specifically, as illustrated in FIG. 68, as a result of the step of forming the slit SL2 in the semiconductors 25A and sacrificial members 41, the slit SL2 has a shape that is longest along the y axis between the upper end and the lower end. In addition, the length of the slit SL2 along the y axis becomes smaller toward each of the upper end and lower end of the slit SL2 from the position of the greatest length.

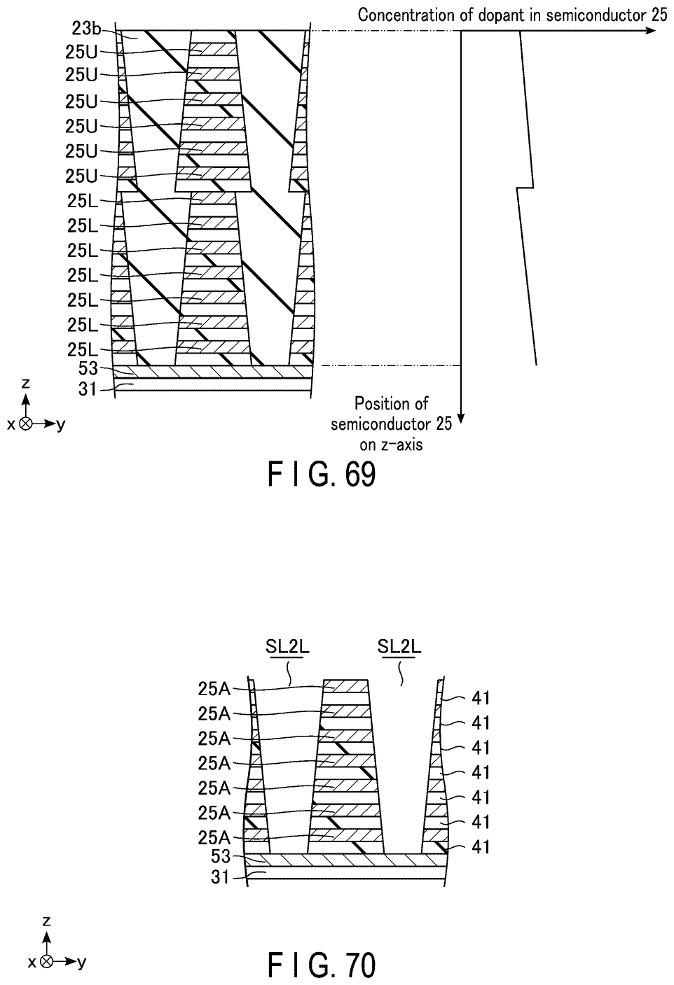

FIG. 69 illustrates still another example of the relationship between the semiconductors and the concentrations of the dopant in the memory device according to the second embodiment. FIG. 69 also illustrates another example of the cross-sectional structure of a part of the memory device of the second embodiment. FIG. 69 illustrates a cross section along the yz plane. In FIG. 69, some structural elements are omitted.

As illustrated in a left side part of FIG. 69, the distribution of the y-axis lengths of the semiconductors 25 along the z axis has such a shape that two distributions, each being the distribution illustrated in the left side part of FIG. 65, are arranged along the z axis. Specifically, the set of the semiconductors 25 include a plurality of semiconductors 25L and a plurality of semiconductors 25U. The semiconductors 25L are included in a lower part of the set of the semiconductors 25, and the semiconductors 25U are included in an upper part of the set of the semiconductors 25. The distribution of the y-axis lengths of the semiconductors 25L along the z axis corresponds to the distribution illustrated in the left side part of FIG. 65. Specifically, a semiconductor 25L located at a higher level has a smaller length along the y axis.

The distribution of the y-axis lengths of the semiconductors 25U along the z axis corresponds to the distribution illustrated in the left side part of FIG. 65. Specifically, a semiconductor 25U located at a higher level has a smaller length along the y axis. The y-axis length of the lowermost semiconductor 25U is greater than the y-axis length of the uppermost semiconductor 25L.

As illustrated in a right side part of FIG. 69, a semiconductor 25U located at a higher level contains a dopant of a lower concentration than a semiconductor 25U located at a lower level. A semiconductor 25L located at a higher level contains a dopant of a lower concentration than a semiconductor 25L located at a lower level. The lowermost semiconductor 25U contains a dopant of a higher concentration than the dopant of the uppermost semiconductor 25L.

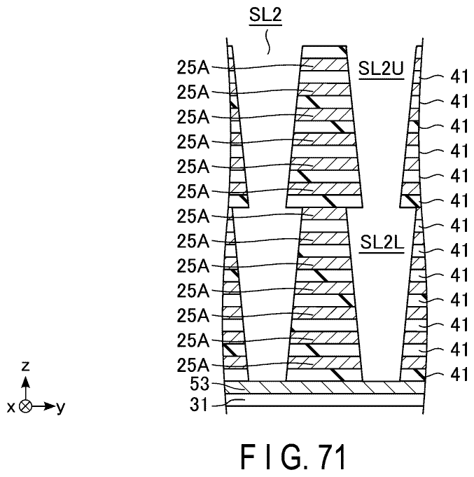

The shapes of the semiconductors 25 result from steps corresponding to the steps illustrated in FIG. 22 to FIG. 25 of the first embodiment. Specifically, in a case where the number of semiconductors 25 arranged along the z axis is large, the set of steps illustrated in FIG. 22 to FIG. 25 can dividedly be performed multiple times. Specifically, as illustrated in FIG. 70, semiconductors 25A, which are processed into semiconductors 25L, and sacrificial members 41, are deposited, and then a lower part SL2L of the slit SL2 is formed in the semiconductors 25A and sacrificial members 41. The lower part SL2L has a taper shape. Next, as illustrated in FIG. 71, semiconductors 25A, which are processed into semiconductors 25U, and sacrificial members 41, are deposited, and then an upper part SL2U of the slit SL2 is formed in the semiconductors 25A and sacrificial members 41. The upper part SL2U has a taper shape. The lower part SL2L and upper part SL2U form the slit SL2. The y-axis length of a lower end of the upper part SL2U is smaller than the y-axis length of an upper end of the lower part SL2L.

The distributions of the concentrations of the dopant along the z axis in FIG. 65, FIG. 67 and FIG. 69 are examples. It suffices that the distribution of concentrations of the dopant of the semiconductors 25 along the z axis corresponds to the distributions of y-axis lengths of the semiconductors 25 along the z axis, as described above with reference to FIG. 65, FIG. 67 and FIG. 69. In addition, the distribution of y-axis lengths of the semiconductors 25 is not limited to the examples of FIG. 65 and FIG. 67. For example, the distribution along the z axis of the y-axis lengths of each of the lower set 25SL and the upper set 25SU can be the distribution illustrated in the left side part of FIG. 67.

According to the second embodiment, as described below, a memory device with a small variance in electrical characteristics of transistors CT can be provided.

In the memory device including three-dimensionally arrayed memory cells, the channel width of the transistor depends on the length of the semiconductor along the y axis. The length of the semiconductor along the y axis depends on the formation of the slit that penetrates, along the z axis, the semiconductors formed at intervals along the z axis. As the number of semiconductors arranged along the z axis becomes greater, the formation of the slit becomes more difficult, and the cross-sectional area of the slit may vary depending on the position of the slit on the z axis. Consequently, the y-axis lengths of the semiconductors may vary. This leads to a variance in electrical characteristics of transistors, in particular, a variance in ON current. Specifically, if different transistors contain dopants of the same concentration, despite the different transistors having different channel widths, a transistor having a greater channel width has only a smaller ON current.

According to the second embodiment, the distribution along the z axis of dopant concentrations of the semiconductors 25 corresponds to the distribution along the z axis of the y-axis lengths of the semiconductors 25. Thus, a transistor CT having a less channel width contains a dopant of a lower concentration, and a transistor CT having a greater channel width contains a dopant of a higher concentration. Therefore, a difference in ON current due to a difference in channel width can be suppressed by the adjustment of the concentration of the dopant.

The second embodiment may be combined with the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first semiconductor;
a first memory element that is in contact with a surface of the first semiconductor on a side of a first direction;
a first insulator on a surface of the first semiconductor on a side of a second direction crossing the first direction;
a first conductor on a surface of the first insulator on the side of the second direction;
a second insulator on a surface of the first semiconductor on a side of a third direction opposite to the second direction;
a second semiconductor located further in the third direction than the first semiconductor;
a second memory element that is in contact with a surface of the second semiconductor on the side of the first direction;
a third insulator on a surface of the second semiconductor on the side of the third direction;
a second conductor on a surface of the third insulator on the side of the third direction;
a fourth insulator on a surface of the second semiconductor on the side of the second direction; and
a third conductor that is in contact with the second insulator and the fourth insulator.

2. The memory device of claim 1, wherein
the first conductor and the second conductor extend in a fourth direction crossing the first direction and the third direction, and
the third conductor extends in a fifth direction opposite to the fourth direction.

3. The memory device of claim 2, further comprising:
a fourth conductor that is in contact with the first conductor at an end of the first conductor on a side of the fourth direction, the fourth conductor extending in the second direction;
a fifth conductor that is in contact with the second conductor at an end of the second conductor on the side of the fourth direction, the fifth conductor extending in the second direction; and
a sixth conductor that is in contact with the third conductor at an end of the third conductor on a side of the fifth direction, the sixth conductor extending in the second direction.

4. The memory device of claim 1, further comprising a seventh conductor that extends in the second direction and is in contact with the first semiconductor and the second semiconductor.

5. The memory device of claim 1, further comprising:
a third semiconductor located further in the second direction than the first semiconductor;
a third memory element that is in contact with a surface of the third semiconductor on the side of the first direction;
a fifth insulator on a surface of the third semiconductor on the side of the third direction;
an eighth conductor on a surface of the fifth insulator on the side of the third direction; and
a sixth insulator located between the first conductor and the eighth conductor, the sixth insulator being in contact with the first conductor and the eighth conductor.

6. The memory device of claim 5, wherein
the first semiconductor and the second semiconductor have a first interval,
the first semiconductor and the third semiconductor have a second interval, and
the second interval is greater than the first interval.

7. The memory device of claim 6, further comprising:
a fourth semiconductor located further in the third direction than the second semiconductor;
a fourth memory element that is in contact with a surface of the fourth semiconductor on the side of the first direction;
a seventh insulator on a surface of the fourth semiconductor on the side of the second direction;
a ninth conductor on a surface of the seventh insulator on the side of the second direction; and
an eighth insulator located between the second conductor and the ninth conductor, the eighth insulator being in contact with the second conductor and the ninth conductor.

8. The memory device of claim 7, wherein
the second semiconductor and the fourth semiconductor have a third interval, and
the third interval is greater than the first interval.

9. The memory device of claim 1, wherein
the first memory element includes a capacitor, and
the second memory element includes a capacitor.

10. A memory device comprising:
a first semiconductor having a first length in a first direction and containing a dopant of a first concentration;
a first memory element that is in contact with a surface of the first semiconductor on a side of a second direction crossing the first direction;
a first insulator on the first semiconductor;
a first conductor on the first insulator;
a second semiconductor spaced apart from the first semiconductor in a third direction crossing the first direction and the second direction, the second semiconductor having a second length different from the first length in the first direction and containing the dopant of a second concentration different from the first concentration;
a second memory element that is in contact with a surface of the second semiconductor on the side of the second direction;
a second insulator on the second semiconductor; and
a second conductor on the second insulator.

11. The memory device of claim 10, wherein
the memory device comprises a plurality of semiconductors including the first semiconductor and the second semiconductor, the semiconductors being spaced apart and arranged in the third direction, and each of the semiconductors including the dopant,
lengths of the semiconductors along the first direction vary toward the third direction, and
a plurality of respective concentrations of the dopant of the semiconductors are distributed based on a distribution of the lengths toward the third direction.

12. The memory device of claim 11, wherein among the semiconductors, a semiconductor having a smaller length along the first direction contains the dopant of a less concentration.

13. The memory device of claim 10, wherein
the first memory element includes a capacitor, and
the second memory element includes a capacitor.
